(19) United States
(12) Patent Application Publication
(10) Pub. No.: US 2025/0234641 A1
(43) Pub. Date: Jul. 17, 2025

(54) SEMICONDUCTOR DEVICE AND METHOD FOR MANUFACTURING THE SAME

(71) Applicant: Samsung Electronics Co., Ltd., Suwon-si (KR)

(72) Inventors: KYEN-HEE LEE, Suwon-si (KR); Jin Myoung LEE, Suwon-si (KR)

(21) Appl. No.: 18/800,139

(22) Filed: Aug. 12, 2024

(30) Foreign Application Priority Data
Jan. 15, 2024 (KR) 10-2024-0006265

(51) Int. Cl. H01L 27/092; H01L 21/822; H01L 21/8238; H01L 29/06; H01L 29/423; H01L 29/66; H01L 29/775; H01L 29/786

(52) U.S. Cl. CPC H10D 84/856; H10D 30/014; H10D 30/43; H10D 30/6735; H10D 30/6757; H10D 62/121; H10D 64/017; H10D 84/0167; H10D 84/0188; H10D 84/038; H10D 88/01

(57) ABSTRACT

A semiconductor device includes, a substrate, a wall structure disposed on the substrate and extending in a first direction, wherein the wall structure includes a first side surface and a second side surface opposite to the first side surface in a second direction intersecting the first direction, a first lower active pattern disposed on the first side surface and including at least one first lower bridge pattern spaced apart from the substrate, a first upper active pattern disposed on the first side surface and including at least one first upper bridge pattern spaced further apart from the substrate than the first lower active pattern, a first gate structure disposed on the first side surface and intersecting the first lower active pattern and the first upper active pattern, a second lower active pattern disposed on the second side surface and including at least one second lower bridge pattern spaced apart from the substrate, a second upper active pattern disposed on the second side surface and including at least one second upper bridge pattern spaced apart from the substrate than the second lower active pattern, and a second gate structure disposed on the second side surface and intersecting the second lower active pattern and the second upper active pattern, wherein a width in the second direction of the wall structure increases as the wall structure extends away from the substrate.

### CROSS-REFERENCE TO RELATED APPLICATION

This application claims priority to Korean Patent Application No. 10-2024-0006265 filed on Jan. 15, 2024 in the Korean Intellectual Property Office, the contents of which in its entirety are herein incorporated by reference.

### BACKGROUND

### Technical Field

The present disclosure relates to a semiconductor device and a method for manufacturing the same. More specifically, the present disclosure relates to a semiconductor device including stacked multi-gate transistors and a method for manufacturing the same.

### Description of Related Art

One of scaling schemes for increasing an integration density of an integrated circuit device includes a multi-gate transistor in which a fin-shaped or nanowire-shaped silicon body is formed on a substrate and a gate is formed on a surface of the silicon body.

Because such a multi-gate transistor uses a three-dimensional channel, it is easy to scale the same. Further, current control capability of the multi-gate transistor may be improved without increasing a gate length of the multi-gate transistor. In addition, the multi-gate transistor may effectively suppress short channel effect (SCE) in which potential of a channel area is affected by drain voltage.

### SUMMARY

One benefit that may be achieved by the embodiments described in present disclosure is that a semiconductor device may have improved performance.

Another benefit that may be achieved by the embodiments described in the present disclosure is improved performance in a method for manufacturing a semiconductor device.

Benefits according to the present disclosure are not limited to the above-mentioned benefits. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

According to an aspect of the present disclosure, a semiconductor device includes, a substrate, a wall structure disposed on the substrate and extending in a first direction, wherein the wall structure includes a first side surface and a second side surface opposite to the first side surface in a second direction intersecting the first direction, a first lower active pattern disposed on the first side surface and including at least one first lower bridge pattern spaced apart from the substrate, a first upper active pattern disposed on the first side surface and including at least one first upper bridge pattern spaced further apart from the substrate than the first lower active pattern, a first gate structure disposed on the first side surface and intersecting the first lower active pattern and the first upper active pattern, a second lower active pattern disposed on the second side surface and including at least one second lower bridge pattern spaced apart from the substrate, a second upper active pattern disposed on the second side surface and including at least one second upper bridge pattern spaced apart from the substrate than the second lower active pattern, and a second gate structure disposed on the second side surface and intersecting the second lower active pattern and the second upper active pattern, wherein a width in the second direction of the wall structure increases as the wall structure extends away from the substrate.

According to an aspect of the present disclosure, a semiconductor device includes, a substrate, a wall structure disposed on the substrate and extending in a first direction, wherein the wall structure includes a first side surface and a second side surface opposite to the first side surface in a second direction intersecting the first direction, a first lower active pattern disposed on the first side surface and including at least one first lower bridge pattern spaced apart from the substrate, a first upper active pattern disposed on the first side surface and including at least one first upper bridge pattern spaced further apart from the substrate than the first lower active pattern, a first gate structure disposed on the first side surface and intersecting the first lower active pattern and the first upper active pattern, a second lower active pattern disposed on the second side surface, and including at least one second lower bridge pattern spaced apart from the substrate, a second upper active pattern disposed on the second side surface and including at least one second upper bridge pattern spaced further apart from the substrate than the second lower active pattern, and a second gate structure disposed on the second side surface and intersecting the second lower active pattern and the second upper active pattern, wherein a width in the second direction of each bridge pattern of the at least one first upper bridge pattern is smaller than a width in the second direction of each bridge pattern of the at least one first lower bridge pattern, wherein a third direction intersects the first direction and the second direction, wherein a thickness in the third direction of each bridge pattern of the at least one first upper bridge pattern is greater than a thickness in the third direction of each bridge pattern of the at least one first lower bridge pattern.

According to an aspect of the present disclosure, a semiconductor device includes, a substrate, a wall structure disposed on the substrate and extending in a first direction, wherein the wall structure includes a first side surface and a second side surface opposite to the first side surface in a second direction intersecting the first direction, a first lower active pattern disposed on the first side surface and including at least one first lower sheet pattern spaced apart from the substrate, a first upper active pattern disposed on the first side surface and including at least one first upper sheet pattern spaced further apart from the substrate than the first lower active pattern, a first gate structure disposed on the first side surface and intersecting the first lower active pattern and the first upper active pattern, a second lower active pattern disposed on the second side surface and including at least one second lower sheet pattern spaced apart from the substrate, a second upper active pattern disposed on the second side surface and including at least one second upper sheet pattern spaced further apart from the substrate than the second lower active pattern, and a second gate structure disposed on the second side surface and intersecting the second lower active pattern and the second upper active pattern, wherein a width in the second direction of each of the at least one first upper sheet pattern is smaller than a width in the second direction of each of the at least one first lower sheet pattern, wherein a number of sheet patterns in the at least one first upper sheet pattern is greater than a number of sheet patterns in the at least one first lower sheet pattern.

According to an aspect of the present disclosure, a method for manufacturing a semiconductor device includes providing a substrate including a first area and a second area, forming a first lower active pattern on the first area, including at least one first lower bridge pattern spaced apart from the substrate, forming a first upper active pattern on the first area, including at least one first upper bridge pattern spaced further apart from the substrate than the first lower active pattern, forming a second lower active pattern on the second area, including at least one second lower bridge pattern spaced apart from the substrate, forming a second upper active pattern on the second area, including at least one second upper bridge pattern spaced further apart from the substrate than the second lower active pattern, forming a wall structure between the first area and the second area so as to extend in a first direction to isolate the first lower active pattern and the second lower active pattern from each other, and isolate the first upper active pattern and the second upper active pattern from each other, forming a first gate structure on the first area so as to intersect the first lower active pattern and the first upper active pattern, and forming a second gate structure on the second area so as to intersect the second lower active pattern and the second upper active pattern, wherein a second direction intersects the first direction, wherein a width in the second direction of the wall structure increases as the wall structure extends away from the substrate.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail illustrative embodiments thereof with reference to the attached drawings, in which:

FIG. 1 is a layout diagram for describing a semiconductor device according to some embodiments.

FIG. 2 is a cross-sectional view taken along line A-A of FIG. 1.

FIG. 3 and FIG. 4 are various enlarged views for describing a R1 area of FIG. 2.

FIG. 5 is a cross-sectional view taken along line B-B of FIG. 1.

FIG. 6 is a cross-sectional view taken along line C-C of FIG. 1.

FIG. 7 is a cross-sectional view for describing a semiconductor device according to some embodiments.

FIG. 8 is a cross-sectional view for describing a semiconductor device according to some embodiments.

FIG. 9 is an enlarged view for describing a R2 area of FIG. 8.

FIG. 10 is a cross-sectional view for describing a semiconductor device according to some embodiments.

FIG. 11 is an enlarged view for describing a R3 area of FIG. 10.

FIGS. 12 to 15 are various cross-sectional views for describing semiconductor devices according to some embodiments.

FIGS. 16 to 41 are diagrams of intermediate structures corresponding to intermediate steps of a method for manufacturing a semiconductor device according to some embodiments.

FIG. 42 is a diagram of an intermediate structure corresponding to an intermediate step of a method for manufacturing a semiconductor device according to some embodiments.

FIG. 43 is a diagram of an intermediate structure corresponding to an intermediate step of a method for manufacturing a semiconductor device according to some embodiments.

### DETAILED DESCRIPTION

The terminology used herein is for the purpose of describing particular embodiments only and is not intended to limit the present disclosure. As used herein, the singular forms “a” and “an” in connection with an item or step are not intended to exclude the existence of additional items or steps, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section later in the specification or in the claims, without departing from the spirit and scope of the present disclosure.

Moreover, terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

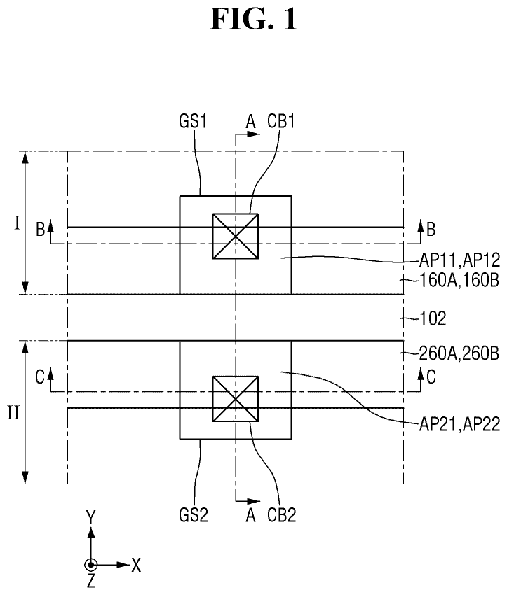

Hereinafter, with reference to FIGS. 1 to 15, a semiconductor device according to some embodiments is described.

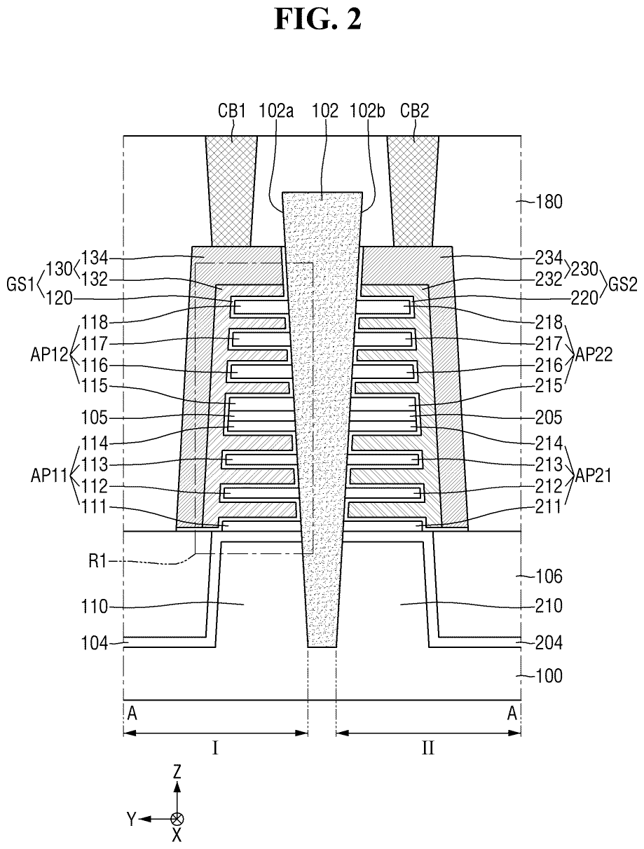

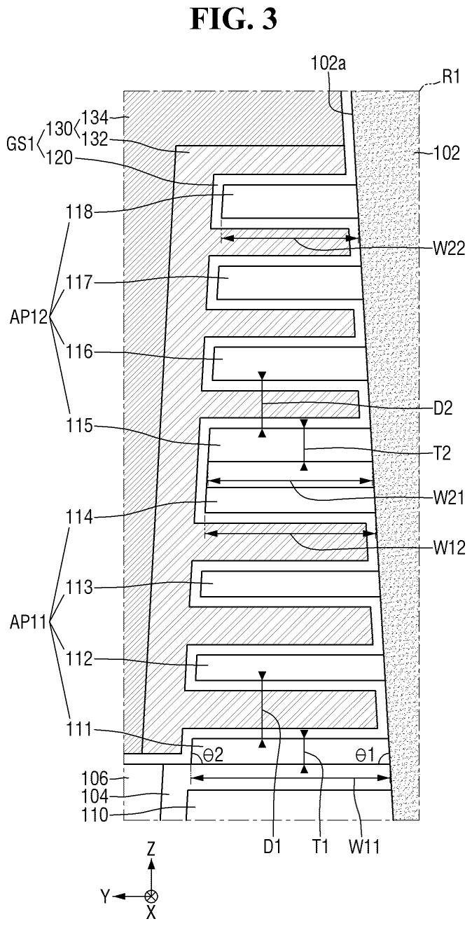

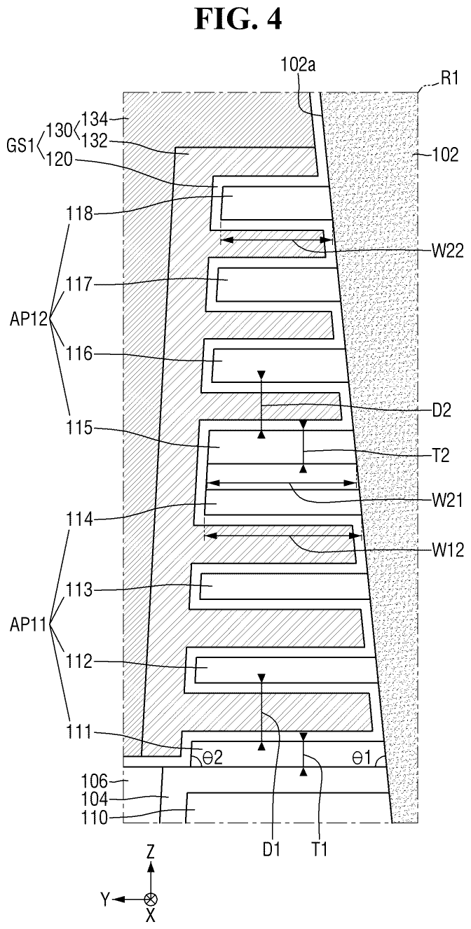

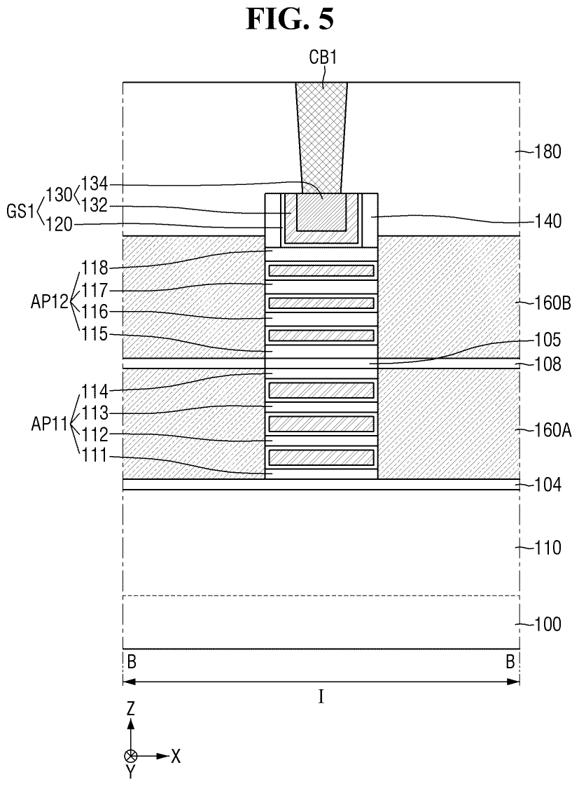

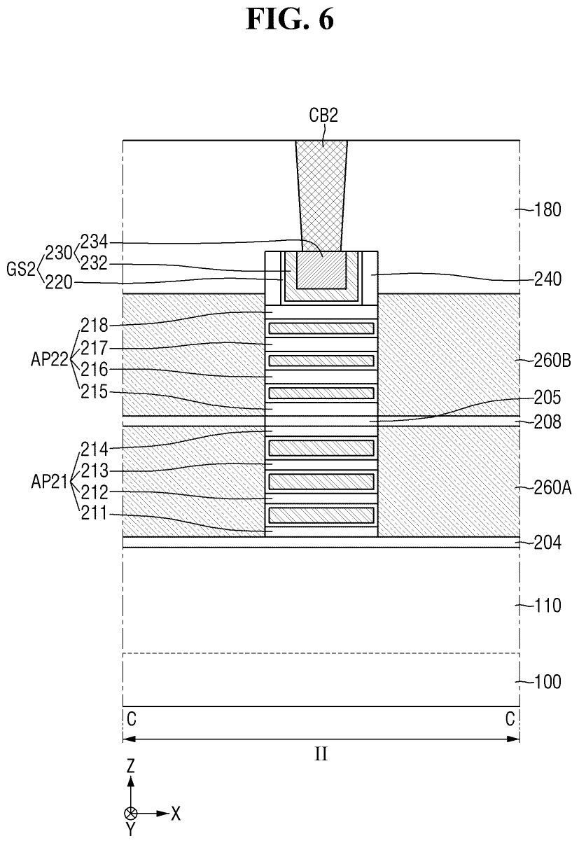

FIG. 1 is a layout diagram for describing a semiconductor device according to some embodiments. FIG. 2 is a cross-sectional view taken along line A-A of FIG. 1. FIG. 3 and FIG. 4 are various enlarged views for describing a R1 area of FIG. 2. FIG. 5 is a cross-sectional view taken along line B-B of FIG. 1. FIG. 6 is a cross-sectional view taken along line C-C of FIG. 1.

Referring to FIGS. 1 to 6, a semiconductor device according to some embodiments may include a substrate 100, a first lower active pattern AP11, a first upper active pattern AP12, a second lower active pattern AP21, a second upper active pattern AP22, a wall structure 102, a first base insulating film 104, a second base insulating film 204, a first middle insulating film 105, a second middle insulating film 205, a field insulating film 106, a first gate structure GS1, a second gate structure GS2, a first gate spacer 140, a second gate spacer 240, a first lower source/drain pattern 160A, a first upper source/drain pattern 160B, a second lower source/drain pattern 260A, a second upper source/drain pattern 260B, an interlayer insulating film 180, a first gate contact CB1 and a second gate contact CB2.

The substrate 100 may be made of bulk silicon or silicon-on-insulator (SOI). Alternatively, the substrate 100 may be embodied as a silicon substrate, or may be made of a material other than silicon, such as silicon germanium, silicon germanium on insulator (SGOI), indium antimonide, lead telluride, indium arsenide, indium phosphide, gallium arsenide or gallium antimonide, but may not limited thereto. Alternatively, the substrate 100 may be composed of a base substrate and an epitaxial layer formed on the base substrate. For convenience of description, an example in which the substrate 100 is embodied as the silicon substrate is described below.

The substrate 100 may include a first area I and a second area II. The first area I and the second area II may be isolated from each other by the wall structure 102 disposed therebetween. For example, the wall structure 102 may extend lengthwise in a first direction X parallel to an upper surface of the substrate 100. An item, layer, or portion of an item or layer described as extending “lengthwise” in a particular direction has a length in the particular direction and a width perpendicular to that direction, where the length is greater than the width. Moreover, the wall structure 102 may include a first side surface 102a and a second side surface 102b opposite to each other in a second direction Y parallel to the upper surface of the substrate 100 and intersecting the first direction X. The first area I may be an area of the substrate 100 defined on the first side surface 102a of the wall structure 102. The second area II may be an area of the substrate 100 defined on the second side surface 102b of the wall structure 102. The wall structure 102 may be, for example, a wall having two opposite side surfaces (e.g., first and second side surfaces 102a and 102b), a top surface, and a bottom surface, when viewed from the first direction X.

In some embodiments, transistors of different conductivity types may be respectively formed in the first area I and the second area II. In one example, the first area I may be a NFET area, and the second area II may be a PFET area. In another example, the first area I may be the PFET area, while the second area II may be the NFET area. However, the technical idea of the present disclosure is not limited thereto, and transistors of the same conductivity type may be formed in the first area I and the second area II.

The first lower active pattern AP11 may be formed on the first area I of the substrate 100. The first lower active pattern AP11 may extend in the first direction X, for example, to be longer in the first direction X than in the second direction Y. The first lower active pattern AP11 may include at least one first lower bridge pattern (e.g., in one embodiment, bridge patterns 111 to 114) that is spaced apart from the substrate 100. For example, at least one first lower bridge pattern (e.g., bridge patterns 111 to 114) may include a first lower sheet pattern 111, a second lower sheet pattern 112, a third lower sheet pattern 113 and a fourth lower sheet pattern 114 which are sequentially stacked on the upper surface of the substrate 100. The first lower sheet pattern 111, the second lower sheet pattern 112, the third lower sheet pattern 113, and the fourth lower sheet pattern 114 may be spaced apart from each other and may extend in the first direction X. This first lower active pattern AP11 may be provided as a channel area of an MBCFET® including a multi-bridge channel. The number of sheet patterns included in the first lower active pattern AP11 is merely illustrative and is not limited to what is shown.

The first upper active pattern AP12 may be formed on the first lower active pattern AP11. The first upper active pattern AP12 may extend in the first direction X. The first upper active pattern AP12 may include at least one first upper bridge pattern (e.g., in one embodiment, bridge patterns 115 to 118) and may be spaced further apart from the substrate than the first lower active pattern. For example, the at least one first upper bridge pattern (e.g., bridge patterns 115 to 118) may include a first upper sheet pattern 115, a second upper sheet pattern 116, a third upper sheet pattern 117 and a fourth upper sheet pattern 118 which are sequentially stacked on an upper surface of the first lower active pattern AP11. The first upper sheet pattern 115, the second upper sheet pattern 116, the third upper sheet pattern 117, and the fourth upper sheet pattern 118 may be spaced apart from each other and may extend in the first direction X. This first upper active pattern AP12 may be provided as a channel area of an MBCFET® including a multi-bridge channel.

In some embodiments, a first fin pattern 110 may be formed between the substrate 100 and the first lower active pattern AP11. The first fin pattern 110 may protrude from an upper surface of the first area I of the substrate 100 and extend lengthwise in the first direction X. The first fin pattern 110 may be formed by etching a portion of the substrate 100, or may be an epitaxial layer grown from the substrate 100. Therefore, the first fin pattern 110 may be part of the substrate or may be added to the substrate, and in either case may be provided with the substrate. The first lower active pattern AP11 and the first upper active pattern AP12 may be stacked sequentially on the first fin pattern 110 in a vertical direction that intersects the upper surface of the substrate 100 (e.g., a third direction Z that intersects the first direction X and the second direction Y).

The second lower active pattern AP21 may be formed on the second area II of the substrate 100. The second lower active pattern AP21 may extend in the first direction X. The second lower active pattern AP21 may include at least one second lower bridge pattern (e.g., bridge patterns 211 to 214) spaced apart from the substrate 100. For example, the at least one second lower bridge pattern (bridge patterns 211 to 214) may include a fifth lower sheet pattern 211, a sixth lower sheet pattern 212, a seventh lower sheet pattern 213 and an eighth lower sheet pattern 214 that are sequentially stacked on the upper surface of the substrate 100. The fifth lower sheet pattern 211, the sixth lower sheet pattern 212, the seventh lower sheet pattern 213, and the eighth lower sheet pattern 214 may be spaced apart from each other and may extend in the first direction X. This second lower active pattern AP21 may be provided as a channel area of an MBCFET® including a multi-bridge channel. The number of sheet patterns included in the second lower active pattern AP21 is merely illustrative and is not limited to what is shown.

The second upper active pattern AP22 may be formed on the second lower active pattern AP21. The second upper active pattern AP22 may extend in the first direction X. The second upper active pattern AP22 may include at least one second upper bridge pattern (e.g., bridge patterns 215 to 218) and may be spaced further apart from the substrate than the second lower active pattern. For example, the at least one second upper bridge pattern (bridge patterns 215 to 218) may include a fifth upper sheet pattern 215, a sixth upper sheet pattern 216, a seventh upper sheet pattern 217, and an eighth upper sheet pattern 218 that are sequentially stacked on an upper surface of the second lower active pattern AP21. The fifth upper sheet pattern 215, the sixth upper sheet pattern 216, the seventh upper sheet pattern 217, and the eighth upper sheet pattern 218 may be spaced apart from each other and extend in the first direction X. This second upper active pattern AP22 may be provided as a channel area of MBCFET® including a multi-bridge channel.

In some embodiments, a second fin pattern 210 may be formed between the substrate 100 and the second lower active pattern AP21. The second fin pattern 210 may be provided with the substrate 100. The second fin pattern 210 may protrude from an upper surface of the second area II of the substrate 100 and extend lengthwise in the first direction X. The second fin pattern 210 may be formed by etching a portion of the substrate 100, or may be an epitaxial layer grown from the substrate 100. The second lower active pattern AP21 and the second upper active pattern AP22 may be arranged sequentially on the second fin pattern 210 in the third direction Z.

Each of the active patterns AP11, AP12, AP21, and AP22 may include silicon (Si) or germanium (Ge) as an elemental semiconductor material. Alternatively, each of the active patterns AP11, AP12, AP21, and AP22 may include a compound semiconductor, for example, a group IV-IV compound semiconductor or a group III-V compound semiconductor. The group IV-IV compound semiconductor may include, for example, a binary compound including two of carbon (C), silicon (Si), germanium (Ge), and tin (Sn), a ternary compound including three thereof, or a compound obtained by doping a group IV element thereto. The group III-V compound semiconductor may include, for example, one of a binary compound, a ternary compound, or a quaternary compound formed by combining at least one of aluminum (Al), gallium (Ga), or indium (In), which are group III elements, and at least one of phosphorus (P), arsenic (As), or antimony (Sb), which are group V elements. For convenience of description, in the following description, the active patterns AP11, AP12, AP21, and AP22 will each be described as a silicon (Si) pattern. Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

In some embodiments, the first lower active pattern AP11 and the second lower active pattern AP21 may be disposed at the same level. The first upper active pattern AP12 and the second upper active pattern AP22 may be disposed at the same level. In this regard, “being disposed at the same level” means being disposed at the same vertical level based on a common reference plane such as the upper surface of the substrate 100 (e.g., being at the same height or distance above the top surface of the substrate 100). For example, as shown, the first lower bridge pattern 111 to 114 and the second lower bridge pattern 211 to 214 may be disposed at the same vertical level. The first upper bridge pattern 115 to 118 and the second upper bridge pattern 215 to 218 may be disposed at the same vertical level.

In some embodiments, the first lower active pattern AP11 and the second lower active pattern AP21 may be formed at the same level. The first upper active pattern AP12 and the second upper active pattern AP22 may be formed at the same level. In some embodiments, items that are “formed at the same level” refers to items that are formed in the same manufacturing process. The first lower active pattern AP11 and the second lower active pattern AP21 may be made of the same material and/or the same material composition. The first upper active pattern AP12 and the second upper active pattern AP22 may be made of the same material and/or the same material composition.

The first base insulating film 104 may be interposed between the substrate 100 and the first lower active pattern AP11. The first base insulating film 104 may electrically insulate the substrate 100 and the first lower active pattern AP11 from each other. For example, the first base insulating film 104 may be interposed between the first fin pattern 110 and the first lower sheet pattern 111. In some embodiments, the first base insulating film 104 may extend conformally along a profile of the upper surface of the substrate 100, and an upper surface and one side surface of the first fin pattern 110.

The second base insulating film 204 may be interposed between the substrate 100 and the second lower active pattern AP21. The second base insulating film 204 may electrically insulate the substrate 100 and the second lower active pattern AP21 from each other. For example, the second base insulating film 204 may be interposed between the second fin pattern 210 and the fifth lower sheet pattern 211. In some embodiments, the second base insulating film 204 may extend conformally along a profile of the upper surface of the substrate 100, an upper surface and one side surface of the second fin pattern 210.

Each of the first base insulating film 104 and the second base insulating film 204 may include, for example, at least one of silicon oxide, silicon nitride, silicon oxynitride, and combinations thereof. However, embodiments of the present disclosure are not limited thereto. In one example, each of the first base insulating film 104 and the second base insulating film 204 may be a silicon nitride film.

In some embodiments, the first base insulating film 104 and the second base insulating film 204 may be disposed at the same level. In some embodiments, the first base insulating film 104 and the second base insulating film 204 may be formed at the same level. For example, portions of the first base insulating film 104 and second base insulating film that are the same horizontal distance from the wall structure 102 may be at the same level.

The first middle insulating film 105 may be interposed between the first lower active pattern AP11 and the first upper active pattern AP12. The first middle insulating film 105 may electrically insulate the first lower active pattern AP11 and the first upper active pattern AP12 from each other. For example, the first middle insulating film 105 may be interposed between the fourth lower sheet pattern 114 and the first upper sheet pattern 115.

The second middle insulating film 205 may be interposed between the second lower active pattern AP21 and the second upper active pattern AP22. The second middle insulating film 205 may electrically insulate the second lower active pattern AP21 and the second upper active pattern AP22 from each other. For example, the second middle insulating film 205 may be interposed between the eighth lower sheet pattern 214 and the fifth upper sheet pattern 215.

Each of the first middle insulating film 105 and the second middle insulating film 205 may include, for example, at least one of silicon oxide, silicon nitride, silicon oxynitride, and combinations thereof. However, embodiments of the present disclosure are not limited thereto. In one example, each of the first middle insulating film 105 and the second middle insulating film 205 may be a silicon nitride film.

In some embodiments, the first middle insulating film 105 and the second middle insulating film 205 may be disposed at the same level. In some embodiments, the first middle insulating film 105 and the second middle insulating film 205 may be formed at the same level.

The field insulating film 106 may be formed on the substrate 100. For example, the field insulating film 106 may be formed on the first base insulating film 104 and the second base insulating film 204. The field insulating film 106 may include, for example, at least one of silicon oxide, silicon nitride, silicon oxynitride, and combinations thereof. However, embodiments of the present disclosure are not limited thereto. In one example, the field insulating film 106 may be a silicon oxide film.

In some embodiments, the field insulating film 106 may fill at least a portion of an area on a side surface of the first fin pattern 110 and at least a portion of an area on a side surface of the second fin pattern 210. In FIG. 2, an upper surface of the field insulating film 106 is shown to be coplanar with an upper surface of the first base insulating film 104 and an upper surface of the second base insulating film 204. However, this is merely an example. In another example, a vertical level of the upper surface of the field insulating film 106 may be lower than a vertical level of each of the upper surface of the first base insulating film 104 and the upper surface of the second base insulating film 204, or may be higher than that of each of the upper surface of the first base insulating film 104 and the upper surface of the second base insulating film 204. Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

The wall structure 102 may extend lengthwise in the first direction X at a location between the first area I and the second area II. The wall structure 102 may isolate the first lower active pattern AP11 and the second lower active pattern AP21 from each other, and isolate the first upper active pattern AP12 and the second upper active pattern AP22 from each other. For example, the first lower active pattern AP11 and the first upper active pattern AP12 may contact a first side surface 102a of the wall structure 102. The second lower active pattern AP21 and the second upper active pattern AP22 may contact a second side surface 102b of the wall structure 102. Each of the active patterns AP11, AP12, AP21, and AP22 may be provided as a channel area of a forksheet field effect transistor (forksheet FET).

The wall structure 102 may include an insulating material such as at least one of silicon oxide, silicon nitride, silicon oxynitride, and combinations thereof. However, embodiments of the present disclosure are not limited thereto. In one example, the wall structure 102 may be a silicon nitride film. The wall structure 102 may be provided as a dielectric wall of a Dielectric Wall Scheme (DWS) forksheet field effect transistor (forksheet FET) structure.

The wall structure 102 may have a tapered shape. Specifically, a width in the second direction Y of the wall structure 102 may increase as the wall structure 102 extends away from the substrate 100. This may be due to the characteristics of an etching process (or a patterning process) to form the wall structure 102. However, embodiments of the present disclosure are not limited thereto.

A lower surface of the wall structure 102 is shown to be coplanar with the upper surface of the substrate 100. This is merely an example. In another example, the lower surface of the wall structure 102 may be formed at a lower vertical level than that of the upper surface of the substrate 100 or may be formed at a higher vertical level than that of the upper surface of the substrate 100.

In some embodiments, the wall structure 102 may isolate the first base insulating film 104 and the second base insulating film 204 from each other. The lower surface of the wall structure 102 may be formed at a lower vertical level than that of each of a lower surface of the first base insulating film 104 and a lower surface of the second base insulating film 204. Moreover, the wall structure 102 may isolate the first middle insulating film 105 and the second middle insulating film 205 from each other.

As the wall structure 102 has the tapered shape, a width of each of the active patterns AP11, AP12, AP21, and AP22 may decrease as each of the active patterns AP11, AP12, AP21, and AP22 extends away from the substrate 100. Moreover, a width of the first upper active pattern AP12 may be smaller than a width of the first lower active pattern AP11. A width of the second upper active pattern AP22 may be smaller than a width of the second lower active pattern AP21. In this regard, the width refers to a width in the second direction Y. For example, as shown in FIG. 3, a width W12 of the fourth lower sheet pattern 114 may be smaller than a width W11 of the first lower sheet pattern 111. A width W22 of the fourth upper sheet pattern 118 may be smaller than a width W21 of the first upper sheet pattern 115. Moreover, a width W21 of the first upper sheet pattern 115 may be smaller than a width W12 of the fourth lower sheet pattern 114. The various sheet pattern widths described above may refer to a maximum width of the pattern in the second direction Y, as the widths of each sheet pattern may decrease in a direction away from the substrate 100.

Moreover, as the wall structure 102 has the tapered shape, each of side surfaces of the active patterns AP11, AP12, AP21, and AP22 facing the wall structure 102 may have an inclination with respect to the upper surface of the substrate 100. For example, as shown in FIG. 3, one side surface of the first lower sheet pattern 111 facing the wall structure 102 may define a first acute angle θ1 with respect to the lower surface of the first lower sheet pattern 111.

In some embodiments, a thickness of each of the first upper bridge patterns 115 to 118 may be greater than a thickness of each of the first lower bridge patterns 111 to 114. In this regard, the thickness refers to a thickness in the third direction Z. For example, as shown in FIG. 3, a thickness T2 of the first upper sheet pattern 115 may be greater than a thickness T1 of the first lower sheet pattern 111.

In some embodiments, each of the plurality of first lower bridge patterns 111 to 114 may have the same thickness (e.g., T1). In some embodiments, each of the plurality of first upper bridge patterns 115 to 118 may have the same thickness (e.g., T2).

In some embodiments, the number of the first upper bridge patterns 115 to 119 may be equal to the number of the first lower bridge patterns 111 to 114. For example, as shown, each of the total number of the first lower bridge patterns 111 to 114 and the total number of the first upper bridge patterns 115 to 119 may be 4.

In some embodiments, a cross-sectional area size of the first upper active pattern AP12 may be equal to a cross-sectional area size of the first lower active pattern AP11. In this regard, the cross-sectional area size refers an area size of a cross section that intersects the first direction X. For example, the thickness (e.g., T2) of each of the first upper bridge patterns 115 to 118 may be controlled such that the combined cross-sectional area size of the first upper bridge patterns 115 to 118 is equal to the combined cross-sectional area size of the first lower bridge patterns 111 to 114.

In some embodiments, a spacing between adjacent ones of the plurality of first upper bridge patterns 115 to 118 may be smaller than a spacing between adjacent ones of the plurality of first lower bridge patterns 111 to 114. For example, as shown in FIG. 3, a spacing D2 between the first upper sheet pattern 115 and the second upper sheet pattern 116 may be smaller than a spacing D1 between the first lower sheet pattern 111 and the second lower sheet pattern 112.

In some embodiments, each of side surfaces of the active patterns AP11, AP12, AP21, and AP22 opposite to the wall structure 102 may also have an inclination with respect to the upper surface of the substrate 100. For example, as shown in FIG. 3, the other side surface of the first lower sheet pattern 111 which is opposite to the wall structure 102 may have an acute angle θ2 with respect to the lower surface of the first lower sheet pattern 111. This may be due to the characteristics of an etching process (or a patterning process) to form the active patterns AP11, AP12, AP21, AP22. However, embodiments of the present disclosure are not limited thereto.

In some embodiments, as shown in FIG. 3, the second acute angle θ2 may be equal to the first acute angle θ1.

In some embodiments, as shown in FIG. 4, the second acute angle θ2 may be different from the first acute angle θ1. In some embodiments, the first acute angle θ1 may be smaller than the second acute angle θ2.

The first gate structure GS1 may be formed on the first area I of the substrate 100. The first gate structure GS1 may intersect with the first lower active pattern AP11 and the first upper active pattern AP12. For example, the first gate structure GS1 may extend in the second direction Y while being disposed on the first side surface 102a of the wall structure 102. The first lower bridge patterns 111 to 114 and the first upper bridge patterns 115 to 118 may extend in the first direction X and extend through the first gate structure GS1. Accordingly, the first gate structure GS1 may surround a perimeter of each of the first lower bridge patterns 111 to 114 and a perimeter of each of the first upper bridge patterns 115 to 118.

The second gate structure GS2 may be formed on the second area II of the substrate 100. The second gate structure GS2 may intersect with the second lower active pattern AP21 and the second upper active pattern AP22. For example, the second gate structure GS2 may extend in the second direction Y while being disposed on the second side surface 102b of the wall structure 102. The second lower bridge patterns 211 to 214 and the second upper bridge patterns 215 to 218 may extend in the first direction X and extend through the second gate structure GS2. Accordingly, the second gate structure GS2 may surround a perimeter of each of the second lower bridge patterns 211 to 214 and a perimeter of each of the second upper bridge patterns 215 to 218.

The first gate structure GS1 may include a first gate dielectric film 120 and a first gate electrode 130. The second gate structure GS2 may include a second gate dielectric film 220 and a second gate electrode 230.

The first gate dielectric film 120 may be disposed on the first lower active pattern AP11 and the first upper active pattern AP12. The first gate dielectric film 120 may conformally extend along surfaces of the first lower bridge patterns 111 to 114, the first upper bridge patterns 115 to 118 and the wall structure 102. The first gate dielectric film 120 may be interposed between the first lower active pattern AP11 and the first gate electrode 130 and between the first upper active pattern AP12 and the first gate electrode 130. The first gate dielectric film 120 may further extend along an upper surface of the first base insulating film 104 and/or an upper surface of the field insulating film 106. Moreover, the first gate dielectric film 120 may extend along a side surface of the first middle insulating film 105.

In some embodiments, a portion of the first gate dielectric film 120 may be interposed between the wall structure 102 and the first gate electrode 130. For example, the first gate dielectric film 120 may extend along the first side surface 102a of the wall structure 102.

The second gate dielectric film 220 may be disposed on the second lower active pattern AP21 and the second upper active pattern AP22. The second gate dielectric film 220 may conformally extend along surfaces of the second lower bridge patterns 211 to 214, the second upper bridge patterns 215 to 218 and the wall structure 102. The second gate dielectric film 220 may be interposed between the second lower active pattern AP21 and the second gate electrode 230 and between the second upper active pattern AP22 and the second gate electrode 230. The second gate dielectric film 220 may further extend along an upper surface of the second base insulating film 204 and/or an upper surface of the field insulating film 106. Moreover, the second gate dielectric film 220 may extend along a side surface of the second middle insulating film 205.

In some embodiments, a portion of the second gate dielectric film 220 may be interposed between the wall structure 102 and the second gate electrode 230. For example, the second gate dielectric film 220 may extend along the second side surface 102b of the wall structure 102.

Each of the first gate dielectric film 120 and the second gate dielectric film 220 may include at least one of, for example, silicon oxide, silicon oxynitride, silicon nitride, or a high dielectric constant material having a higher dielectric constant than that of silicon oxide. The high dielectric constant material may include at least one of for example, hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}) or combinations thereof. However, embodiments of the present disclosure are not limited thereto.

The semiconductor device according to some embodiments may include a negative capacitance (NC) FET using a negative capacitor. For example, the first gate dielectric film 120 and/or the second gate dielectric film 220 may include a ferroelectric material film with ferroelectric properties and a paraelectric material film with paraelectric properties.

The ferroelectric material film may have negative capacitance, and the paraelectric material film may have positive capacitance. For example, when two or more capacitors are connected in series to each other, and capacitance of each of the capacitors has a positive value, a total capacitance is smaller than capacitance of each individual capacitor. On the contrary, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. In this connection, in one example, hafnium zirconium oxide may refer to a material obtain by doping hafnium oxide with zirconium (Zr). In another example, hafnium zirconium oxide may refer to a compound of hafnium (Hf), zirconium (Zr), and oxygen (O).

The ferroelectric material film may further contain dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). A type of the dopant contained in the ferroelectric material film may vary depending on a type of the ferroelectric material included in the ferroelectric material film.

When the ferroelectric material film includes hafnium oxide, the dopant contained in the ferroelectric material film may include, for example, at least one of gadolinium (Gd), silicon (Si), zirconium (Zr), aluminum (Al), and yttrium (Y).

When the dopant is aluminum (Al), the ferroelectric material film may include about 3 to about 8 at % (atomic %) of aluminum. In this connection, a content of the dopant may be a content of aluminum based on a sum of hafnium and aluminum.

When the dopant is silicon (Si), the ferroelectric material film may include about 2 to about 10 at % of silicon. When the dopant is yttrium (Y), the ferroelectric material film may include about 2 to about 10 at % yttrium. When the dopant is gadolinium (Gd), the ferroelectric material film may include about 1 to about 7 at % gadolinium. When the dopant is zirconium (Zr), the ferroelectric material film may include about 50 to about 80 at % zirconium.

The paraelectric material film may have paraelectric properties. The paraelectric material film may include, for example, at least one of silicon oxide and metal oxide having a high dielectric constant. Although the metal oxide contained in the paraelectric material film may include, for example, at least one of hafnium oxide, zirconium oxide and aluminum oxide. However, the present disclosure is not limited thereto.

The ferroelectric material film and the paraelectric material film may include or be formed of the same material or composition of material. The ferroelectric material film may have ferroelectric properties, but the paraelectric material film may not have the ferroelectric properties. For example, when each of the ferroelectric material film and the paraelectric material film includes hafnium oxide, a crystal structure of hafnium oxide contained in the ferroelectric material film is different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 to about 10 nm, the present disclosure is not limited thereto. Because a critical thickness exhibiting the ferroelectric properties may be vary based on a type of the ferroelectric material, the thickness of the ferroelectric material film may vary depending on the type of the ferroelectric material.

In one example, the first gate dielectric film 120 and/or the second gate dielectric film 220 may include one ferroelectric material film. In another example, the first gate dielectric film 120 and/or the second gate dielectric film 220 may include a plurality of ferroelectric material films spaced apart from each other. The first gate dielectric film 120 and/or the second gate dielectric film 220 may have a stack film structure in which a plurality of ferroelectric material films and a plurality of paraelectric material films are alternately stacked on top of each other.

The first gate electrode 130 may be disposed on the first gate dielectric film 120. In some embodiments, the first gate electrode 130 may be formed by stacking a plurality of conductive films. For example, the first gate electrode 130 may include a first work function adjustment film 132 that controls a work function, and a first filling conductive film 134 that fills a space defined by the first work function adjustment film 132.

The second gate electrode 230 may be disposed on the second gate dielectric film 220. In some embodiments, the second gate electrode 230 may be formed by stacking a plurality of conductive films. For example, the second gate electrode 230 may include a second work function adjustment film 232 which controls a work function, and a second filling conductive film 234 that fills a space defined by the second work function adjustment film 232.

The first work function adjustment film 132 and the second work function adjustment film 232 are shown to have the same thickness. However, this is only an example. In another example, the first work function adjustment film 132 and the second work function adjustment film 232 have different thicknesses.

Each of the first work function adjustment film 132 and the second work function adjustment film 232 may include, for example, at least one of TiN, TaN, TiC, TaC, TiAlC, and combinations thereof. However, embodiments of the present disclosure are not limited thereto. Each of the first filling conductive film 134 and the second filling conductive film 234 may include, for example, W or Al. However, embodiments of the present disclosure are not limited thereto.

In some embodiments, the wall structure 102 may extend in the first direction X so as to isolate the first gate structure GS1 and the second gate structure GS2 from each other. For example, an upper surface of the wall structure 102 may be formed at a higher vertical level than that of each of an upper surface of the first gate structure GS1 and an upper surface of the second gate structure GS2.

The first gate spacer 140 may extend along a side surface of the first gate structure GS1. In some embodiments, a portion of the first gate dielectric film 120 may be interposed between the first gate electrode 130 and the first gate spacer 140. For example, as shown in FIG. 5, the first gate dielectric film 120 may extend further along at least a portion of an inner side surface of the first gate spacer 140. The first gate dielectric film 120 may be formed in a replacement process. However, embodiments of the present disclosure are not limited thereto.

The second gate spacer 240 may extend along a side surface of the second gate structure GS2. In some embodiments, a portion of the second gate dielectric film 220 may be interposed between the second gate electrode 230 and the second gate spacer 240. For example, as shown in FIG. 6, the second gate dielectric film 220 may extend further along at least a portion of an inner side surface of the second gate spacer 240. The second gate dielectric film 220 may be formed in a replacement process. However, embodiments of the present disclosure are not limited thereto.

Each of the first gate spacer 140 and the second gate spacer 240 may include at least one of, for example, silicon nitride, silicon oxynitride, silicon oxycarbide, silicon boron nitride, silicon boron carbonitride, silicon oxycarbonitride, and combinations thereof. However, embodiments of the present disclosure are not limited thereto. In one example, each of the first gate spacer 140 and the second gate spacer 240 are a silicon nitride film.

The first lower source/drain pattern 160A and the first upper source/drain pattern 160B may be formed on at least one side surface of the first gate structure GS1. For example, the first lower source/drain pattern 160A may be formed on two opposite sides of the first gate structure GS1 to form a first source/drain region and a second source/drain region, and the first upper source/drain pattern 160B may be formed on two opposite sides of the first gate structure GS1 to form a first source/drain region and a second source/drain region. The first lower source/drain pattern 160A may contact the first lower active pattern AP11 in the first direction X. The first upper source/drain pattern 160B may contact the first upper active pattern AP12 in the first direction X. For example, the first lower bridge patterns 111 to 114 may extend through the first gate structure GS1 and the first gate spacer 140 so as to contact the first lower source/drain pattern 160A. Moreover, the first upper bridge pattern 115 to 118 may extend through the first gate structure GS1 and the first gate spacer 140 so as to contact the first upper source/drain pattern 160B. The first lower source/drain pattern 160A and the first upper source/drain pattern 160B may be electrically insulated from the first gate electrode 130 via the first gate spacer 140 and/or the first gate dielectric film 120.

In some embodiments, each of the first lower source/drain pattern 160A and the first upper source/drain pattern 160B may be an epitaxial layer. For example, the first lower source/drain pattern 160A may be formed in an epitaxial growth manner from the first lower active pattern AP11. The first upper source/drain pattern 160B may be formed in an epitaxial growth manner from the first upper active pattern AP12.

When the first area I is an NFET area, each of the first lower source/drain pattern 160A and the first upper source/drain pattern 160B may contain n-type impurities (e.g., phosphorus (P), antimony (Sb) or arsenic (As)) or impurities to prevent diffusion of the n-type impurities. When the first area I is an NFET area, each of the first lower source/drain pattern 160A and the first upper source/drain pattern 160B may further contain a tensile stress material. In one example, when each of the first lower active pattern AP11 and the first upper active pattern AP12 is embodied as a silicon (Si) pattern, each of the first lower source/drain pattern 160A and the first upper source/drain pattern 160B may include a material (e.g., silicon carbide (SiC)) with a smaller lattice constant than that of silicon (Si).

In some embodiments, the first lower source/drain pattern 160A and the first upper source/drain pattern 160B may be electrically insulated from each other. For example, as shown in FIG. 5, a first isolation insulating film 108 may be formed between the first lower source/drain pattern 160A and the first upper source/drain pattern 160B. A thickness of the first isolation insulating film 108 is shown to be equal to a thickness of the first middle insulating film 105. However, this is only an example. In another example, the thickness of the first isolation insulating film 108 may be different from the thickness of the first middle insulating film 105.

The second lower source/drain pattern 260A and the second upper source/drain pattern 260B may be formed on at least one side surface of the second gate structure GS2. For example, the second lower source/drain pattern 260A may be formed on two opposite sides of the second gate structure GS2 to form a first source/drain region and a second source/drain region, and the second upper source/drain pattern 260B may be formed on two opposite sides of the second gate structure GS2 to form a first source/drain region and a second source/drain region. The second lower source/drain pattern 260A may contact the second lower active pattern AP21 in the first direction X. The second upper source/drain pattern 260B may contact the second upper active pattern AP22 in the first direction X. For example, the second lower bridge patterns 211 to 214 may extend through the second gate structure GS2 and the second gate spacer 240 so as to contact the second lower source/drain pattern 260A. Moreover, the second upper bridge patterns 215 to 218 may extend through the second gate structure GS2 and the second gate spacer 240 so as to contact the second upper source/drain pattern 260B. The second lower source/drain pattern 260A and the second upper source/drain pattern 260B may be electrically insulated from the second gate electrode 230 via the second gate spacer 240 and/or the second gate dielectric film 220.

In some embodiments, each of the second lower source/drain pattern 260A and the second upper source/drain pattern 260B may include or be an epitaxial layer. For example, the second lower source/drain pattern 260A may be formed in an epitaxial growth manner from the second lower active pattern AP21. The second upper source/drain pattern 260B may be formed in an epitaxial growth manner from the second upper active pattern AP22.

When the second area II is a PFET area, each of the second lower source/drain pattern 260A and the second upper source/drain pattern 260B may contain p-type impurities (e.g., boron (B), indium (In), gallium (Ga) or aluminum (Al)), or impurities to prevent diffusion of the p-type impurities. When the second area II is a PFET area, each of the second lower source/drain pattern 260A and the second upper source/drain pattern 260B may further include a compressive stress material. In one example, when each of the second lower active pattern AP21 and the second upper active pattern AP22 is embodied as a silicon (Si) pattern, each of the second lower source/drain pattern 260A and the second upper source/drain pattern 260B may include a material (e.g., silicon germanium (SiGe)) with a larger lattice constant than that of silicon (Si).

In some embodiments, the second lower source/drain pattern 260A and the second upper source/drain pattern 260B may be electrically insulated from each other. For example, as shown in FIG. 6, a second isolation insulating film 208 may be formed between the second lower source/drain pattern 260A and the second upper source/drain pattern 260B. A thickness of the second isolation insulating film 208 is shown to be equal to a thickness of the second middle insulating film 205. However, this is only an example. In another example, the thickness of the second isolation insulating film 208 may be different from the thickness of the second middle insulating film 205.

The interlayer insulating film 180 may be formed on the wall structure 102, the gate structures GS1 and GS2, and the source/drain patterns 160A, 160B, 260A, and 260B. The interlayer insulating film 180 may cover the wall structure 102, the gate structures GS1 and GS2, and the source/drain patterns 160A, 160B, 260A, and 260B.

The interlayer insulating film 180 may include at least one, for example, silicon oxide, silicon nitride, silicon oxynitride, silicon oxycarbide, silicon boron nitride, silicon boron carbonitride, silicon oxycarbonitride, and low dielectric constant materials with a smaller dielectric constant than that of silicon oxide. However, embodiments of the present disclosure are not limited thereto. The low dielectric constant material may include, for example, Flowable Oxide (FOX), Torene SilaZene (TOSZ), Undoped Silica Glass (USG), Borosilica Glass (BSG), PhosphoSilica Glass (PSG), BoroPhosphoSilica Glass (BPSG), Plasma Enhanced Tetra Ethyl Ortho Silicate (PETEOS), Fluoride Silicate Glass (FSG), Carbon Doped silicon Oxide (CDO), Xerogel, Aerogel, Amorphous Fluorinated Carbon, Organo Silicate Glass (OSG), Parylene, bis-benzocyclobutenes (BCB), SiLK, polyimide, porous polymeric material, and combinations thereof. However, embodiments of the present disclosure are not limited thereto.

The first gate contact CB1 may be electrically connected to the first gate structure GS1. For example, the first gate contact CB1 may extend in the third direction Z through the interlayer insulating film 180, and may contact an upper surface of the first gate electrode 130.

The second gate contact CB2 may be electrically connected to the second gate structure GS2. For example, the second gate contact CB2 may extend in the third direction Z through the interlayer insulating film 180 and may contact an upper surface of the second gate electrode 230.

Each of the first gate contact CB1 and the second gate contact CB2 may include a conductive material such as a metal such as cobalt (Co), titanium (Ti), tantalum (Ta), ruthenium (Ru), tungsten (W), or cobalt tungsten phosphorus (CoWP), etc. However, embodiments of the present disclosure are not limited thereto.

As the semiconductor device becomes more highly integrated, a semiconductor device using stacked multi-gate transistors is being researched to implement a larger number of semiconductor devices in the same area. This semiconductor device may include a lower multi-gate transistor on the substrate and an upper multi-gate transistor stacked on the lower multi-gate transistor.

In one example, in a Dielectric Wall Scheme (DWS) forksheet field effect transistor (forksheet FET) structure including the stacked multi-gate transistors, the wall structure 102 which serves as a dielectric wall may have a tapered shape in which a width thereof is decreased as the wall structure extends downwards. In this case, a channel width of the upper multi-gate transistor may be smaller than a channel width of the lower multi-gate transistor, and a difference between characteristics of the lower multi-gate transistor and the upper multi-gate transistor may occur.

The semiconductor device according to some embodiments may minimize the difference between the characteristics of the lower multi-gate transistor and the upper multi-gate transistor by controlling a channel area size of the lower multi-gate transistor and/or the upper multi-gate transistor. For example, as described above, the thickness (e.g., T2) of each first upper bridge pattern 115 to 118 may be greater than the thickness (e.g., T1) of each first lower bridge pattern 111 to 114. Moreover, in some embodiments, the thickness (e.g., T2) of each first upper bridge patterns 115 to 118 may be controlled such that the cross-sectional area size of the combined first upper bridge patterns 115 to 118 is equal to the cross-sectional area size of the combined first lower bridge patterns 111 to 114. For example, a particular group of bridge patterns (e.g., sheet patterns) may together form a channel region, between a source and drain region, for a transistor. The group of bridge patterns may comprise all of the bridge patterns for the corresponding transistor, and may be described as a multi-sheet channel pattern. In some embodiments, a multi-sheet channel pattern for an upper transistor (e.g., first upper bridge pattern 115 to 118) may have the same cross-sectional area, as viewed from the direction in which the wall structure 102 extends lengthwise (e.g., the first direction X), as a multi-sheet pattern for a lower transistor (e.g., first lower bridge pattern 111 to 114), even though lengths of the sheet patterns in a direction perpendicular to the direction in which the wall structure 102 extends lengthwise (e.g., the second direction Y) may be different. In some embodiments, the cross-sectional area of the first lower active pattern AP11 is within a particular percent difference from the cross-sectional area of the first upper active pattern AP12 (e.g., from 0% to 5% difference). Similar differences may occur between other corresponding upper and lower active patterns. Thus, the difference between the characteristics of the lower multi-gate transistor and the upper multi-gate transistor may be minimized such that the semiconductor device with improved performance may be provided.

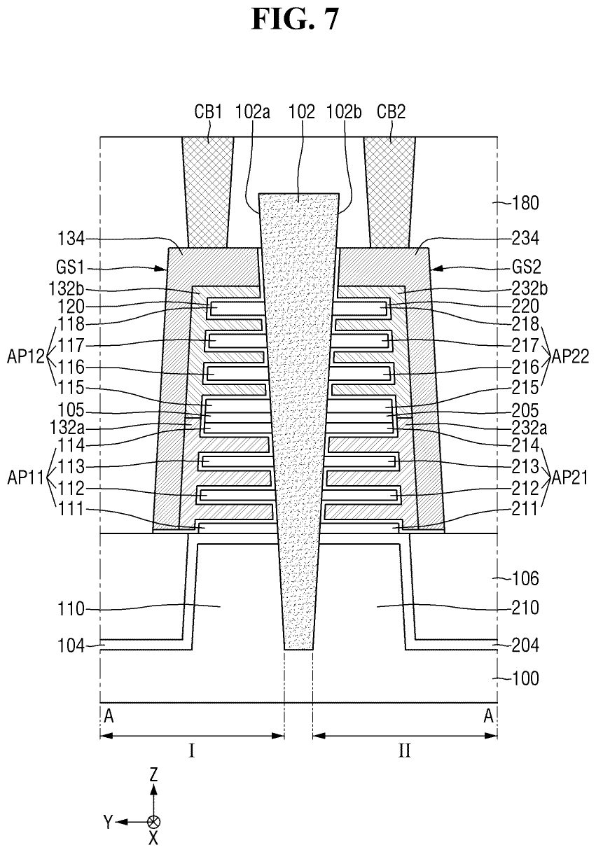

FIG. 7 is a cross-sectional view for describing a semiconductor device according to some embodiments. For convenience of description, descriptions duplicate with those set forth above with reference to FIGS. 1 to 6 are briefly set forth or omitted.

Referring to FIG. 7, in a semiconductor device according to some embodiments, the first gate electrode 130 may include a first lower work function adjustment film 132a and a first upper work function adjustment film 132b. The second gate electrode 230 may include a second lower work function adjustment film 232a and a second upper work function adjustment film 232b.

The first lower work function adjustment film 132a may intersect with the first lower active pattern AP11. The first upper work function adjustment film 132b may intersect with the first upper active pattern AP12. The second lower work function adjustment film 232a may intersect with the second lower active pattern AP21. The second upper work function adjustment film 232b may intersect with the second upper active pattern AP22.

Each of the first lower work function adjustment film 132a, the first upper work function adjustment film 132b, the second lower work function adjustment film 232a, and the second upper work function adjustment film 232b may include at least one of, for example, TiN, TaN, TiC, TaC, TiAlC, and combinations thereof. However, embodiments of the present disclosure are not limited thereto.

In some embodiments, the first lower work function adjustment film 132a and the first upper work function adjustment film 132b may be respective work function adjustment films of different conductivity types. The second lower work function adjustment film 232a and the second upper work function adjustment film 232b may be respective work function adjustment films of different conductivity types. In one example, each of the first lower work function adjustment film 132a and the second lower work function adjustment film 232a may be a work adjustment function film of NFET, and each of the first upper work function adjustment film 132b and the second upper work function adjustment film 232b may be a work function adjustment film of PFET. In another example, each of the first lower work function adjustment film 132a and the second lower work function adjustment film 232a may be a work adjustment function film of PFET, while each of the first upper work function adjustment film 132b and the second upper work function adjustment film 232b may be a work function adjustment film of NFET. In still another example, each of the first lower work function adjustment film 132a and the second upper work function adjustment film 232b may be a work function adjustment film of NFET, while each of the first upper work function adjustment film 132b and the second lower work function adjustment film 232a may be a work function adjustment film of PFET.

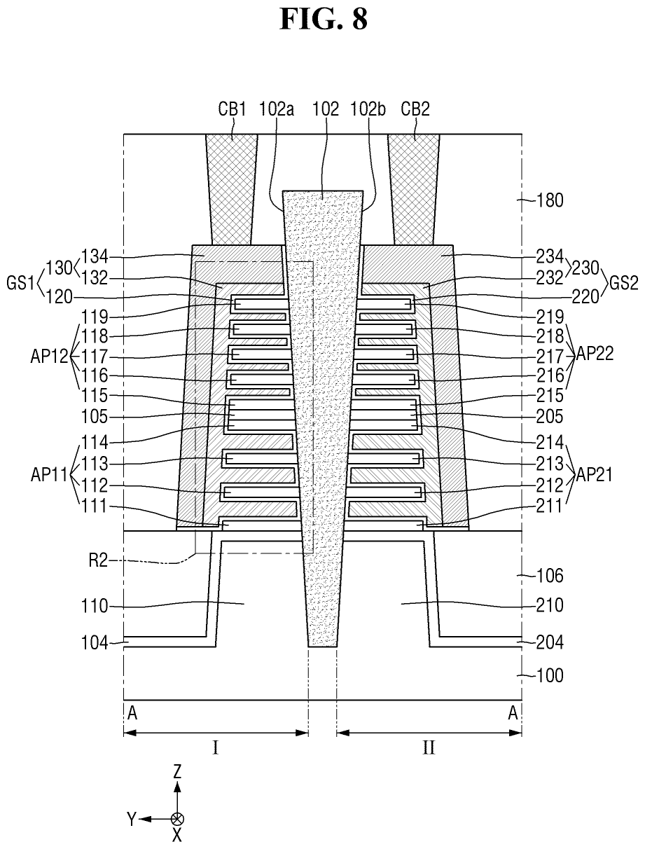

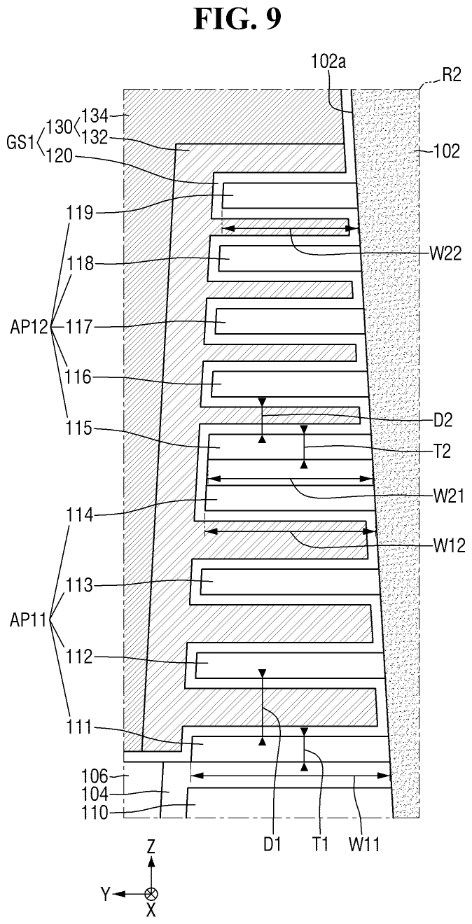

FIG. 8 is a cross-sectional view for describing a semiconductor device according to some embodiments. FIG. 9 is an enlarged view for describing a R2 area of FIG. 8. For convenience of description, descriptions duplicate with those set forth above with reference to FIGS. 1 to 6 are briefly set forth or omitted.

Referring to FIG. 8 and FIG. 9, in a semiconductor device according to some embodiments, the number of the at least one first upper bridge patterns (e.g., bridge patterns 115 to 119) may be greater than the number of the at least one first lower bridge patterns (e.g., bridge patterns 111 to 114). For example, the first upper bridge patterns 115 to 119 may further include a fifth upper sheet pattern 119. Therefore, the number of the first lower bridge pattern 111 to 114 may be 4, while the number of the first upper bridge pattern 115 to 119 may be 5

In some embodiments, the thickness of each of the first upper bridge patterns 115 to 119 may be equal to the thickness of each of the first lower bridge patterns 111 to 114. For example, as shown in FIG. 9, the thickness T2 of the first upper sheet pattern 115 may be equal to the thickness T1 of the first lower sheet pattern 111.

In some embodiments, the plurality of first lower bridge patterns 111 to 114 may have the same thickness (e.g., T1). In some embodiments, the plurality of first upper bridge patterns 115 to 119 may have the same thickness (e.g., T2).

In some embodiments, the cross-sectional area size of the first upper active pattern AP12 may be equal to the cross-sectional area size of the first lower active pattern AP11. For example, the number of the at least one first upper bridge patterns (e.g., 115 to 119) may be controlled such that the cross-sectional area size of the first upper bridge patterns 115 to 119 is equal to the cross-sectional area size of the first lower bridge patterns 111 to 114. Thus, the difference between the characteristics of the lower multi-gate transistor and the upper multi-gate transistor may be minimized such that the semiconductor device with improved performance may be provided.

In some embodiments, the spacing between adjacent ones of the plurality of first upper bridge patterns 115 to 119 may be smaller than the spacing between adjacent ones of the plurality of first lower bridge patterns 111 to 114. For example, as shown in FIG. 9, the spacing D2 between the first upper sheet pattern 115 and the second upper sheet pattern 116 may be smaller than the spacing D1 between the first lower sheet pattern 111 and the second lower sheet pattern 112.

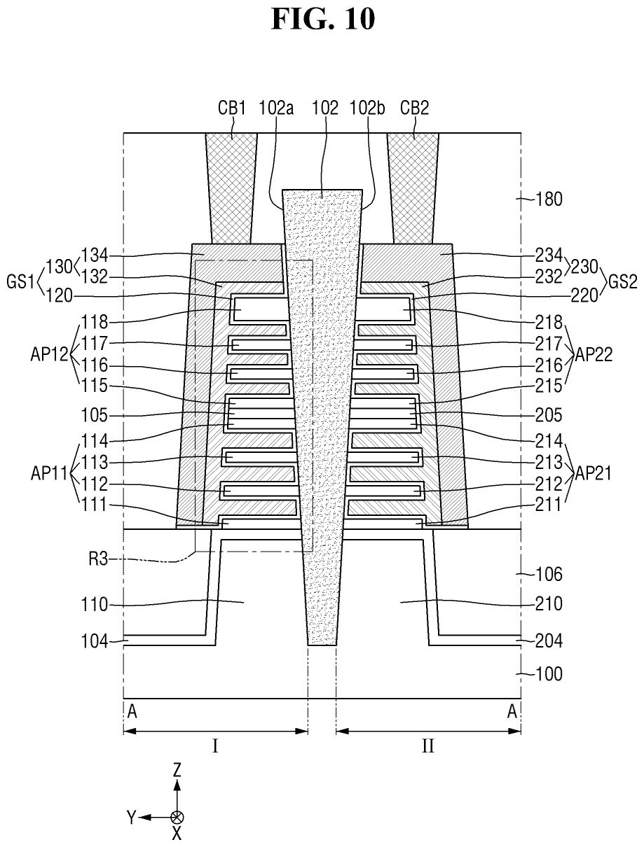

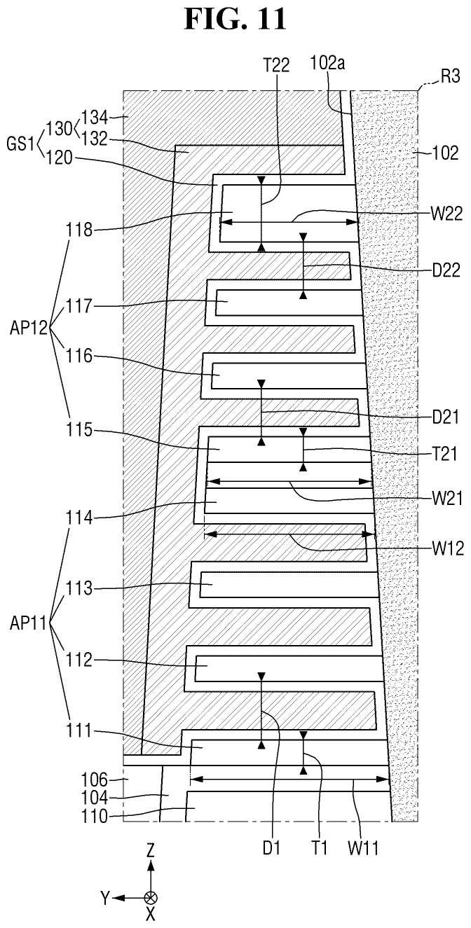

FIG. 10 is a cross-sectional view for describing a semiconductor device according to some embodiments. FIG. 11 is an enlarged view for describing a R3 area of FIG. 10. For convenience of description, descriptions duplicate with those set forth above with reference to FIGS. 1 to 6 are briefly set forth or omitted.

Referring to FIG. 10 and FIG. 11, in a semiconductor device according to some embodiments, each of some of the plurality of first upper bridge patterns 115 to 118 may have a different thickness from that of each of the others of the plurality of first upper bridge patterns 115 to 118.

For example, a thickness T21 of each of the first upper sheet pattern 115, the second upper sheet pattern 116, and the third upper sheet pattern 117 may be equal to the thickness (e.g., T1) of each bridge pattern of the first lower bridge patterns 111 to 114. A thickness T22 of the fourth upper sheet pattern 118 may be greater than the thickness (e.g., T1) of each of the first lower bridge patterns 111 to 114.

In some embodiments, the cross-sectional area size of the first upper active pattern AP12 may be equal to the cross-sectional area size of the first lower active pattern AP11. For example, the thickness T22 of the fourth upper sheet pattern 118 may be controlled such that the cross-sectional area size of the first upper bridge patterns 115 to 118 is equal to the cross-sectional area size of the first lower bridge patterns 111 to 114.

In some embodiments, the spacing between adjacent ones of the plurality of first upper bridge patterns 115 to 118 may be smaller than the spacing between adjacent ones of the plurality of first lower bridge patterns 111 to 114. For example, as shown in FIG. 9, a spacing D21 between the first upper sheet pattern 115 and the second upper sheet pattern 116 and/or a spacing D22 between the third upper sheet pattern 117 and the fourth upper sheet pattern 118 may be smaller than the spacing D1 between the first lower sheet pattern 111 and the second lower sheet pattern 112.

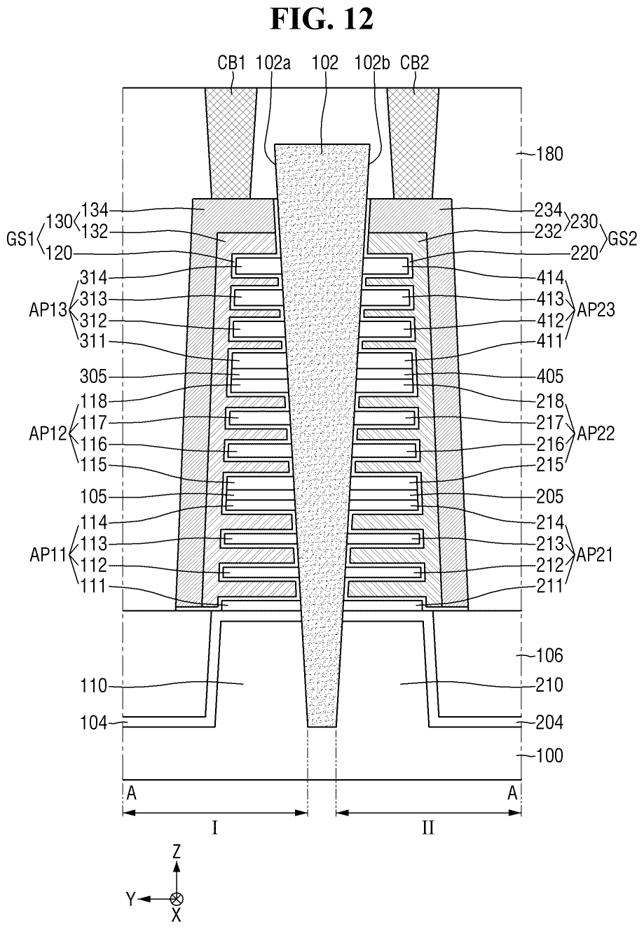

FIGS. 12 to 15 are various cross-sectional views for describing semiconductor devices according to some embodiments, respectively. For convenience of description, descriptions duplicate with those set forth above with reference to FIGS. 1 to 6 are briefly set forth or omitted.

Referring to FIGS. 12 to 15, the semiconductor device according to some embodiments further includes a third upper active pattern AP13, a fourth upper active pattern AP23, a third middle insulating film 305, and a fourth middle insulating film 405.

The third upper active pattern AP13 may be formed on the first upper active pattern AP12. The third upper active pattern AP13 may be spaced further apart from the substrate 100 than the first upper active pattern AP12. The first gate structure GS1 may intersect with the third upper active pattern AP13.

The fourth upper active pattern AP23 may be formed on the second upper active pattern AP22. The fourth upper active pattern AP23 may be spaced further apart from the substrate 100 than the second upper active pattern AP22. The second gate structure GS2 may intersect with the fourth upper active pattern AP23.

The third middle insulating film 305 may be interposed between the first upper active pattern AP12 and the third upper active pattern AP13. The third middle insulating film 305 may electrically insulate the first upper active pattern AP12 and the third upper active pattern AP13 from each other.

The fourth middle insulating film 405 may be interposed between the second upper active pattern AP22 and the fourth upper active pattern AP23. The fourth middle insulating film 405 may electrically insulate the second upper active pattern AP22 and the fourth upper active pattern AP23 from each other.

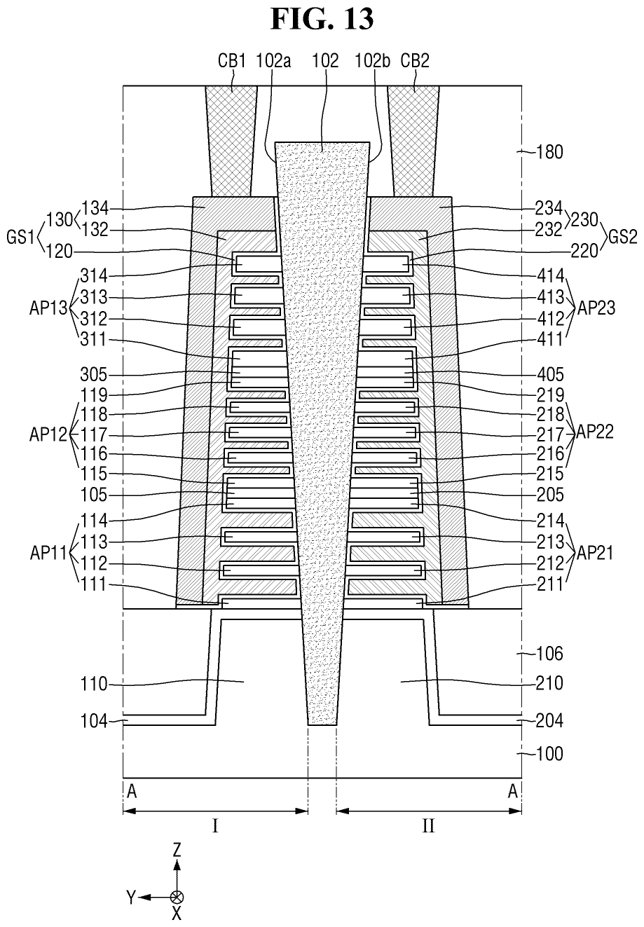

Referring to FIG. 12 and FIG. 13, in the semiconductor device according to some embodiments, the third upper active pattern AP13 may include at least one third upper bridge pattern (e.g., bridge patterns 311 to 314). The fourth upper active pattern AP23 may include at least one fourth upper bridge pattern (e.g., bridge patterns 411 to 414).

Referring to FIG. 12, in the semiconductor device according to some embodiments, the thickness of each first upper bridge pattern 115 to 118 may be greater than the thickness of each first lower bridge pattern 111 to 114. Moreover, a thickness of each third upper bridge pattern 311 to 314 may be greater than the thickness of each first upper bridge pattern 115 to 118. In some embodiments, a cross-sectional area size of the third upper active pattern AP13 may be equal to the cross-sectional area size of the first upper active pattern AP12.

Referring to FIG. 13, in the semiconductor device according to some embodiments, the number of the first upper bridge patterns 115 to 119 may be greater than the number of the first lower bridge patterns 111 to 114. Moreover, a thickness of each of the third upper bridge patterns 311 to 314 may be greater than the thickness of each of the first lower bridge patterns 111 to 114 and/or the thickness of each of the first upper bridge patterns 115 to 118. In some embodiments, the cross-sectional area size of the third upper active pattern AP13 may be equal to the cross-sectional area size of the first upper active pattern AP12.

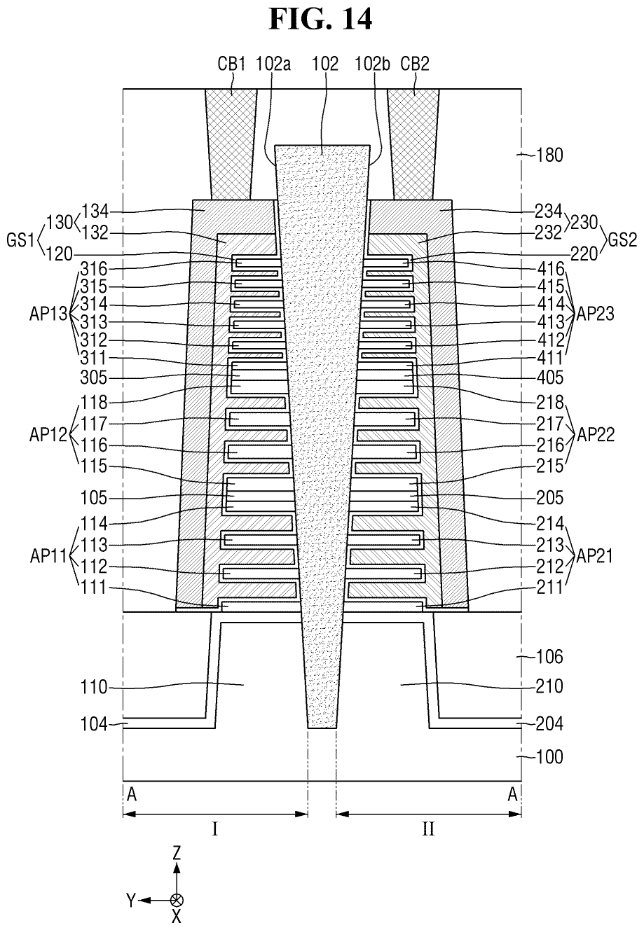

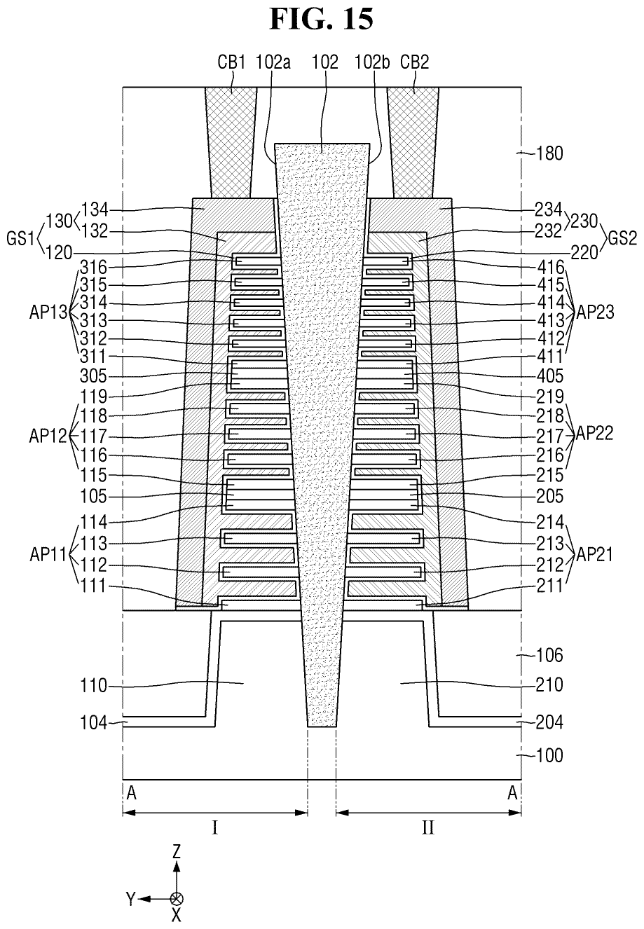

Referring to FIG. 14 and FIG. 15, in the semiconductor device according to some embodiments, the third upper active pattern AP13 may include at least one third upper bridge pattern 311 to 316. The fourth upper active pattern AP23 may include at least one fourth upper bridge pattern 411 to 416.

Referring to FIG. 14, in the semiconductor device according to some embodiments, a thickness of each of the at least one first upper bridge pattern 115 to 118 may be greater than the thickness of each of the at least one first lower bridge pattern 111 to 114. Moreover, the number of bridge patterns of the at least one third upper bridge pattern 311 to 316 may be greater than the number of bridge patterns of the at least one first upper bridge pattern 115 to 118. In some embodiments, the cross-sectional area size of the third upper active pattern AP13 may be equal to the cross-sectional area size of the first upper active pattern AP12.

Referring to FIG. 15, in the semiconductor device according to some embodiments, the number of bridge patterns of the at least one first upper bridge patterns 115 to 119 may be greater than the number of bridge patterns of the at least one first lower bridge patterns 111 to 114. Moreover, the number of bridge patterns of the at least one third upper bridge pattern 311 to 314 may be greater than the number of bridge patterns of the at least one first upper bridge pattern 115 to 118. In some embodiments, the cross-sectional area size of the third upper active pattern AP13 may be equal to the cross-sectional area size of the first upper active pattern AP12.

Hereinafter, with reference to FIGS. 1 to 43, a method for manufacturing a semiconductor device according to some embodiments is described.

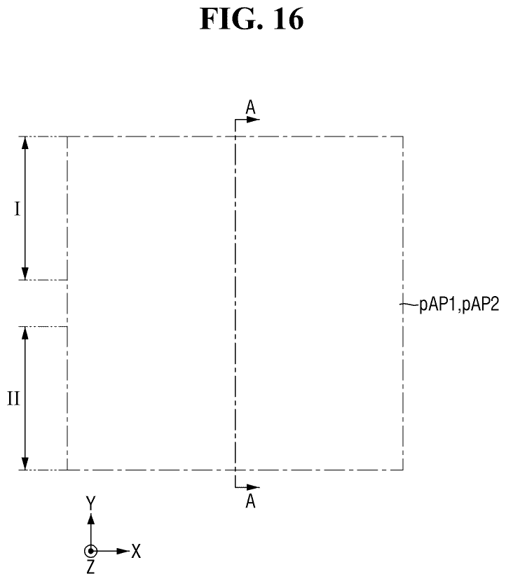

FIGS. 16 to 41 are diagrams of intermediate structures corresponding to intermediate steps of a method for manufacturing a semiconductor device according to some embodiments. For convenience of description, descriptions duplicate with those set forth above with reference to FIGS. 1 to 15 are briefly set forth or omitted.

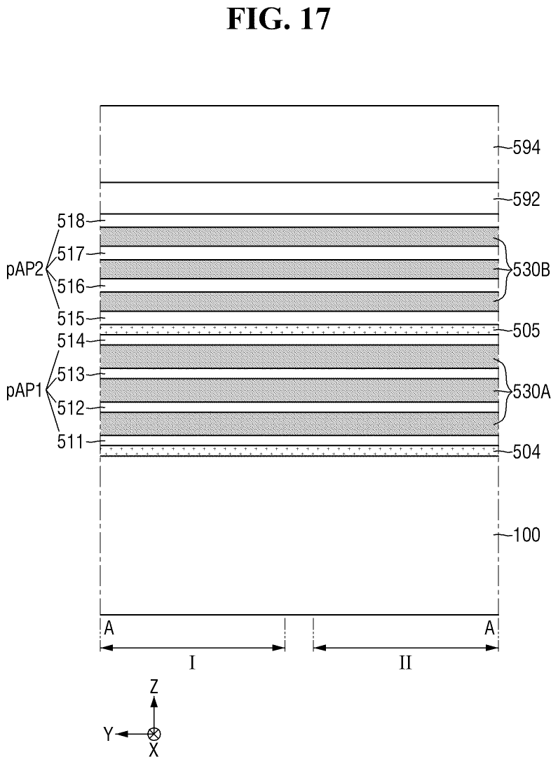

Referring to FIG. 16 and FIG. 17, a base sacrificial film 504, a first active film pAP1, a first sacrificial film 530A, a middle sacrificial film 505, and a second active film pAP2, a second sacrificial film 530B and at least one protective film 592 and 594 are formed on the substrate 100. For reference, FIG. 17 is a cross-sectional view taken along line A-A of FIG. 16.

The base sacrificial film 504 may be formed on the substrate 100. The first active films pAP1 and the first sacrificial films 530A may be alternately stacked on top of each other while being disposed on the base sacrificial film 504. For example, the first active film pAP1 may include at least one lower active film (e.g., active films 511 to 514) that are sequentially stacked on the base sacrificial film 504. The first sacrificial film 530A may be interposed between adjacent ones of the lower active films 511 to 514 and may space apart the adjacent ones of the lower active films 511 to 514 from each other in the vertical direction (e.g., the third direction Z).

The middle sacrificial film 505 may be formed on the first active film pAP1 and the first sacrificial film 530A. The second active films pAP2 and the second sacrificial films 530B may be alternately stacked on top of each other while being disposed on the middle sacrificial film 505. For example, the second active film pAP2 may include upper active films 515 to 518 that are sequentially stacked on the middle sacrificial film 505. The second sacrificial film 530B may be interposed between adjacent ones of the upper active films 515 to 518 and may space apart the adjacent ones of the upper active films 515 to 518 from each other in the vertical direction (e.g., the third direction Z).

In some embodiments, a thickness of each active film of the at least one upper active film 515 to 518 may be greater than a thickness of each active film of the at least one lower active film 511 to 514.

The first sacrificial film 530A and the second sacrificial film 530B may have an etch selectivity with respect to the first active film pAP1 and the second active film pAP2, respectively. In one example, each of the first active film pAP1 and the second active film pAP2 may include a silicon (Si) film, while each of the first sacrificial film 530A and the second sacrificial film 530B may include a silicon germanium (SiGe) film.

Each of the base sacrificial film 504 and the middle sacrificial film 505 may have an etch selectivity with respect to the substrate 100, the first active film pAP1, the first sacrificial film 530A, the second active film pAP2, and the second sacrificial film 530B. In one example, each of the first sacrificial film 530A and the second sacrificial film 530B may include a silicon germanium (SiGe) film containing germanium (Ge) at a first concentration. Each of the base sacrificial film 504 and the middle sacrificial film 505 may include a silicon germanium (SiGe) film containing germanium (Ge) at a second concentration greater than the first concentration.

The at least one protective film 592 and 594 may be formed on the second active film pAP2 and the second sacrificial film 530B. The at least one protective film 592 and 594 may include a variety of materials to protect the first active film pAP1, the first sacrificial film 530A, the second active film pAP2, and/or the second sacrificial film 530B in subsequent processes. In one example, the first protective film 592 including silicon oxide (SiO) and the second protective film 594 including amorphous silicon (a-Si) may be sequentially stacked on the second active film pAP2 and the second sacrificial film 530B.

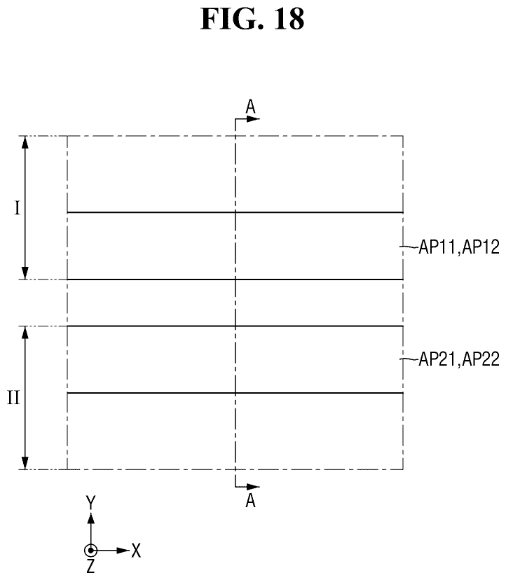

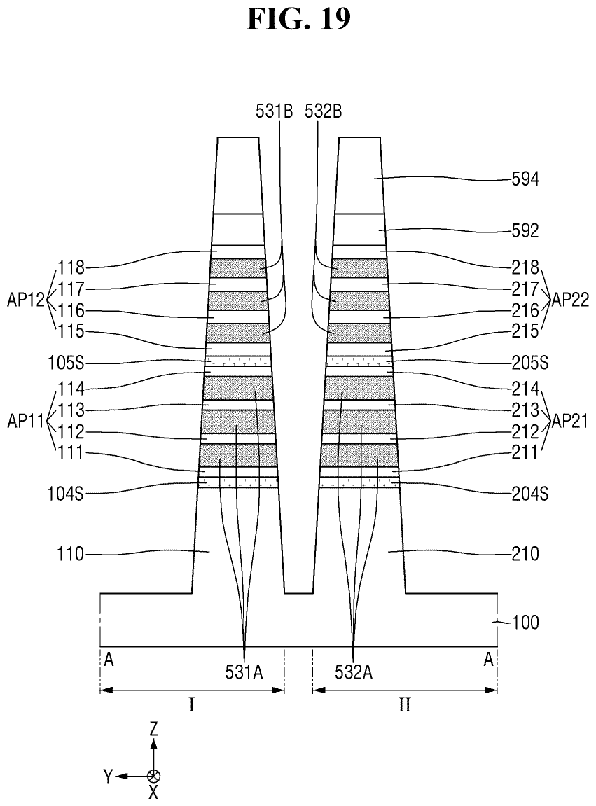

Referring to FIG. 18 and FIG. 19, a first base sacrificial pattern 104S, a second base sacrificial pattern 204S, a first lower active pattern AP11, and a first lower sacrificial pattern 531A, a second lower active pattern AP21, a second lower sacrificial pattern 532A, a first middle sacrificial pattern 105S, a second middle sacrificial pattern 205S, a first upper active pattern AP12, a first upper sacrificial pattern 531B, a second upper active pattern AP22 and a second upper sacrificial pattern 532B are formed on the substrate 100. For reference, FIG. 19 is a cross-sectional view taken along line A-A of FIG. 18.

Each of the first base sacrificial pattern 104S, the second base sacrificial pattern 204S, the first lower active pattern AP11, the first lower sacrificial pattern 531A, the second lower active pattern AP21, the second lower sacrificial pattern 532A, the first middle sacrificial pattern 105S, the second middle sacrificial pattern 205S, the first upper active pattern AP12, the first upper sacrificial pattern 531B, the second upper active pattern AP22, and the second upper sacrificial pattern 532B may extend in the first direction X. For example, a patterning process may be performed to pattern the base sacrificial film 504, the first active film pAP1, the first sacrificial film 530A, the middle sacrificial film 505, the second active film pAP2, the second the sacrificial film 530B and the at least one protective film 592 and 594 of FIG. 16 and FIG. 17.

In some embodiments, in the process of etching the base sacrificial film 504, a portion of the substrate 100 may be etched to form the first fin pattern 110 on the first area I and the second fin pattern 210 on the second area II.

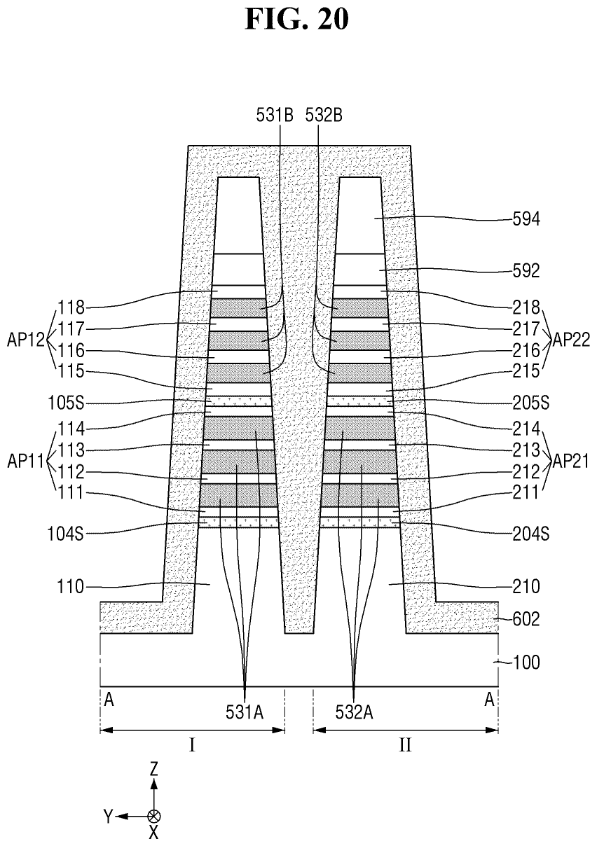

Referring to FIG. 20, a first filling insulating film 602 is formed.

The first filling insulating film 602 may fill an area between the first lower active pattern AP11 and the second lower active pattern AP21 and an area between the first upper active pattern AP12 and the second upper active pattern AP22. For example, the first filling insulating film 602 may cover a resulting structure of FIG. 19. The first filling insulating film 602 may include, for example, at least one of silicon oxide, silicon nitride, silicon oxynitride, and combinations thereof. However, embodiments of the present disclosure are not limited thereto. In one example, the first filling insulating film 602 may include a silicon nitride film.

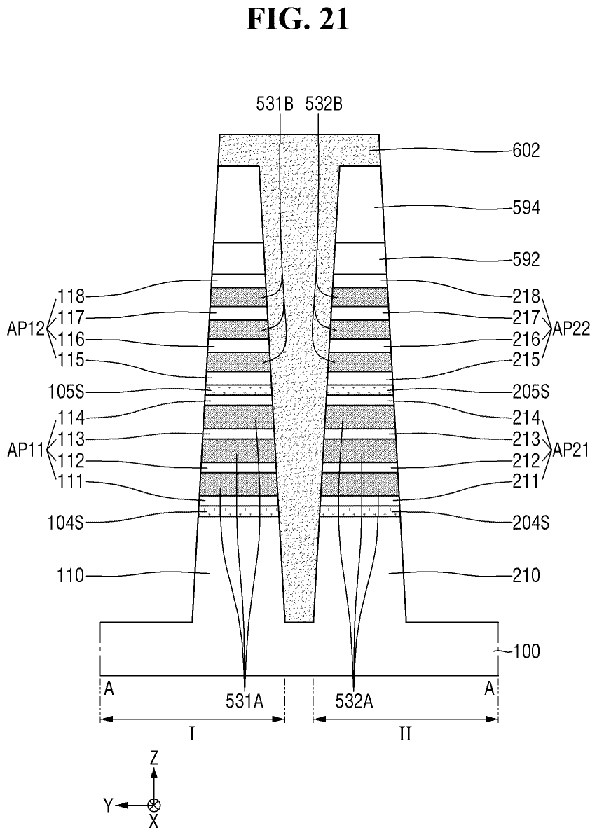

Referring to FIG. 21, the first base sacrificial pattern 104S, the second base sacrificial pattern 204S, the first middle sacrificial pattern 105S, and the second middle sacrificial pattern 205S are exposed.

For example, a portion of the first filling insulating film 602 may be removed such that a side surface of the first base sacrificial pattern 104S, a side surface of the second base sacrificial pattern 204S, a side surface of the first middle sacrificial pattern 105S, and a side surface of the second middle sacrificial pattern 205S may be exposed. In some embodiments, a portion of the first filling insulating film 602 filling the area between the first lower active pattern AP11 and the second lower active pattern AP21 and the area between the first upper active pattern AP12 and the second upper active pattern AP22 may not be removed.

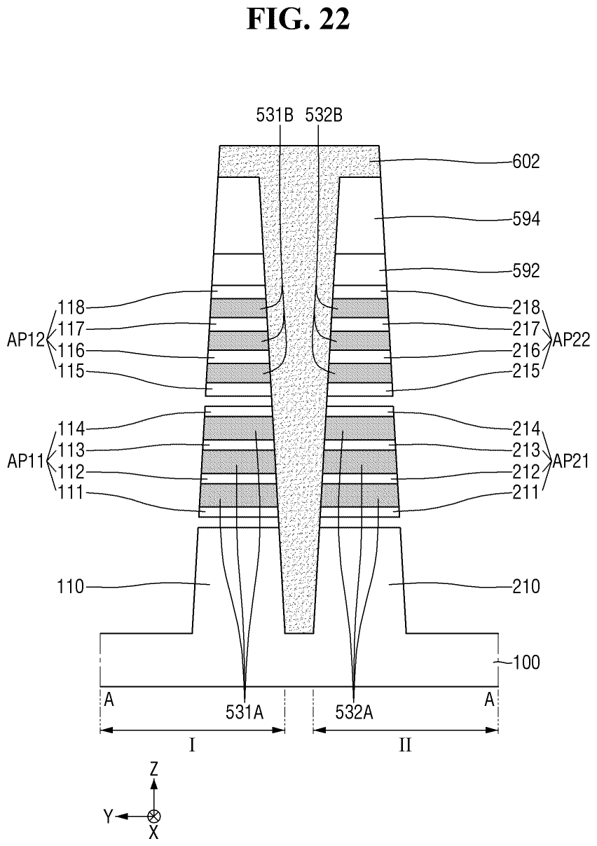

Referring to FIG. 22, the first base sacrificial pattern 104S, the second base sacrificial pattern 204S, the first middle sacrificial pattern 105S, and the second middle sacrificial pattern 205S are removed.

Each of the first base sacrificial pattern 104S, the second base sacrificial pattern 204S, the first middle sacrificial pattern 105S and the second middle sacrificial pattern 205S may have an etch selectivity relative to the substrate 100, the active patterns AP11, AP12, AP21 and AP22 and the sacrificial patterns 531A, 532A, 531B, and 532B, and thus may be selectively removed.

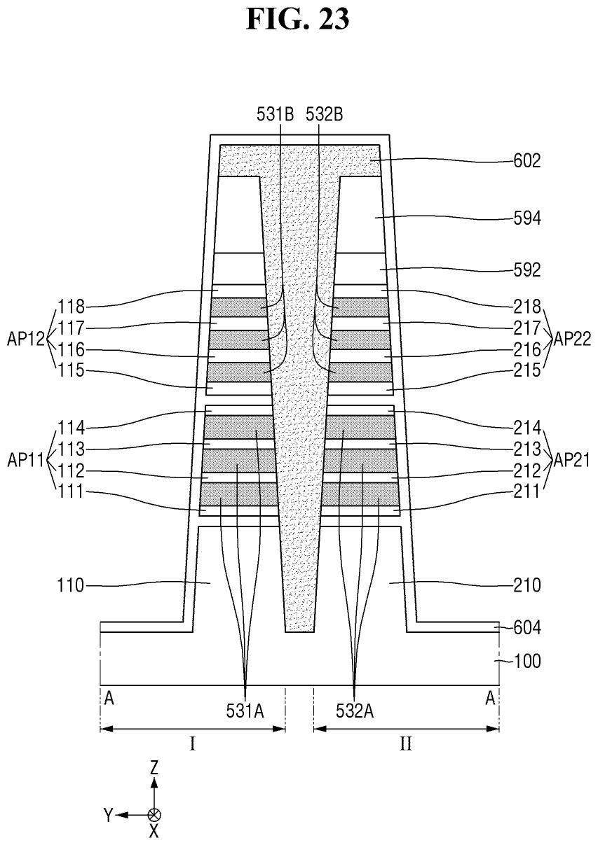

Referring to FIG. 23, a second filling insulating film 604 is formed.

The second filling insulating film 604 may fill an area obtained by removing the first base sacrificial pattern 104S, the second base sacrificial pattern 204S, the first middle sacrificial pattern 105S and the second middle sacrificial pattern 205S. For example, the second filling insulating film 604 may cover a resulting structure of FIG. 22. The second filling insulating film 604 may include, for example, at least one of silicon oxide, silicon nitride, silicon oxynitride, and combinations thereof. However, embodiments of the present disclosure are not limited thereto. In one example, the second filling insulating film 604 may include a silicon nitride film.

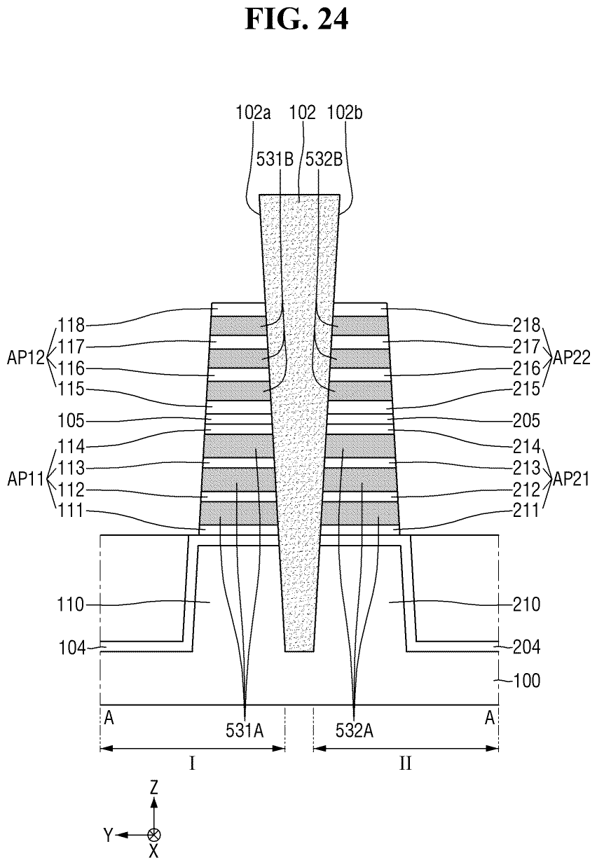

Referring to FIG. 24, the wall structure 102, the first base insulating film 104, the second base insulating film 204, the first middle insulating film 105, and the second middle insulating film 205 are formed.

For example, the field insulating film 106 may be formed on the second filling insulating film 604. The field insulating film 106 may not cover the active patterns AP11, AP12, AP21, and AP22 and the sacrificial patterns 531A, 532A, 531B, and 532B so as to be exposed. For example, the upper surface of the field insulating film 106 may be formed at a lower vertical level than that of the lower surface of the first lower sheet pattern 111.

Subsequently, a recess process on the second filling insulating film 604 may be performed. Thus, the first base insulating film 104 may be formed between the substrate 100 and the first lower active pattern AP11, and the second base insulating film 204 may be formed between the substrate 100 and the second lower active pattern AP21.

Subsequently, the first filling insulating film 602 disposed on the at least one protective film 592 and 594 may be removed. Subsequently, the at least one protective film 592 and 594 may be removed. Thus, the wall structure 102 isolating the first lower active pattern AP11 and the second lower active pattern AP21 from each other, and isolating the first upper active pattern AP12 and the second upper active pattern AP22 from each other may be formed.

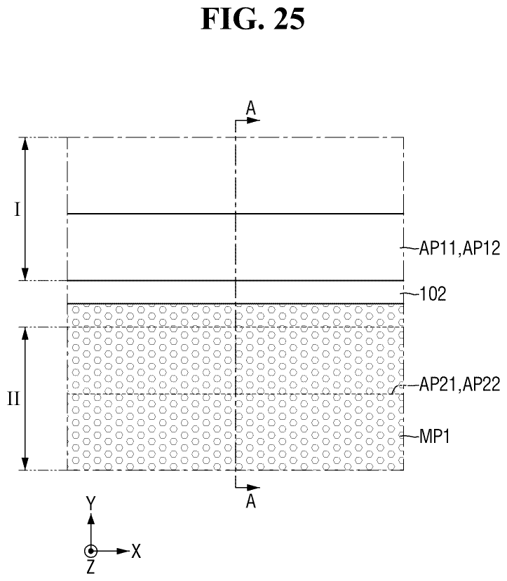

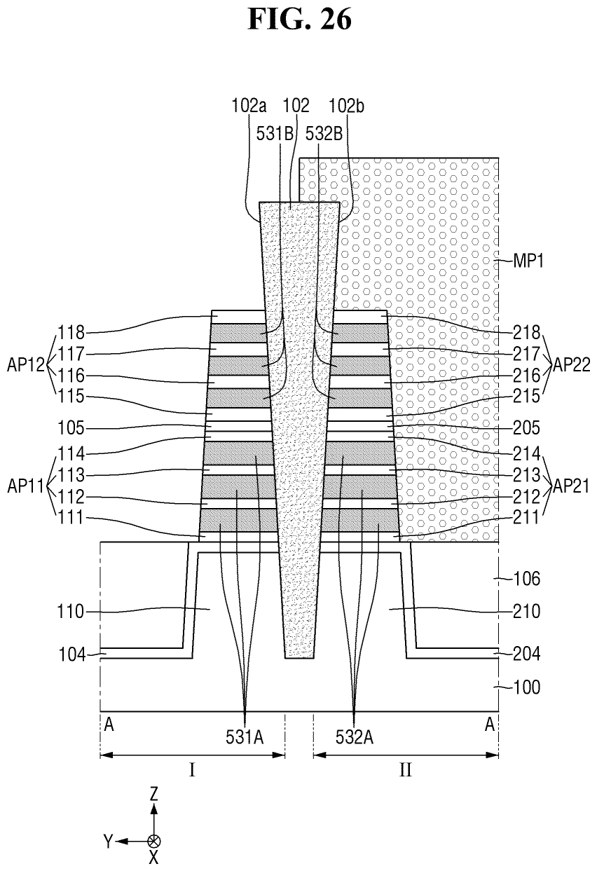

Referring to FIG. 25 and FIG. 26, a first mask pattern MP1 is formed on the second area II of the substrate 100. For reference, FIG. 26 is a cross-sectional view taken along line A-A of FIG. 25.

The first mask pattern MP1 may cover the second area II of the substrate 100. For example, the first mask pattern MP1 may cover the second lower active pattern AP21, the second lower sacrificial pattern 532A, the second upper active pattern AP22, and the second upper sacrificial pattern 532B. The first mask pattern MP1 may cover at least a portion of the wall structure 102. However, embodiments of the present disclosure are not limited thereto.

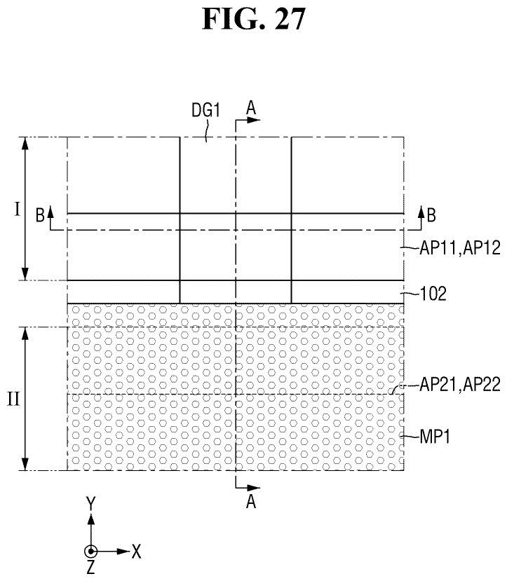

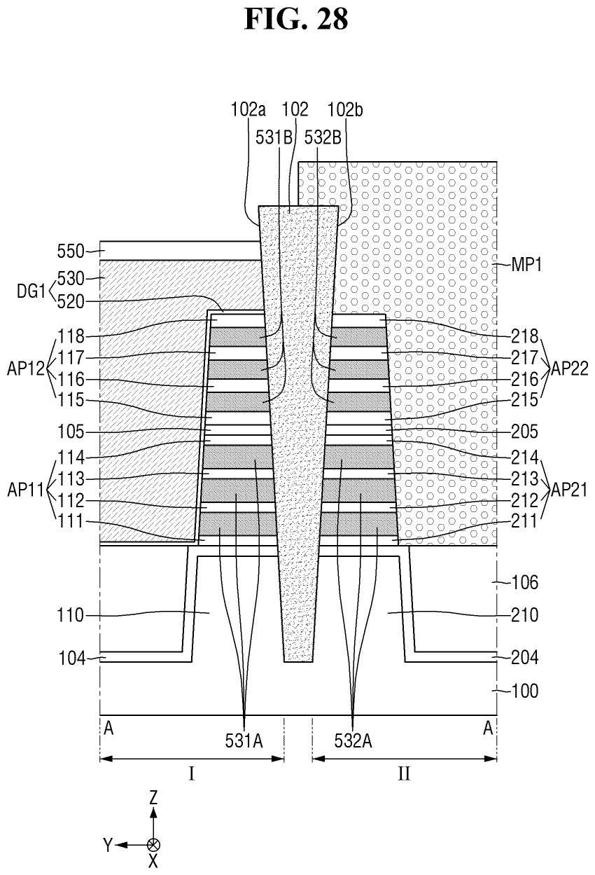

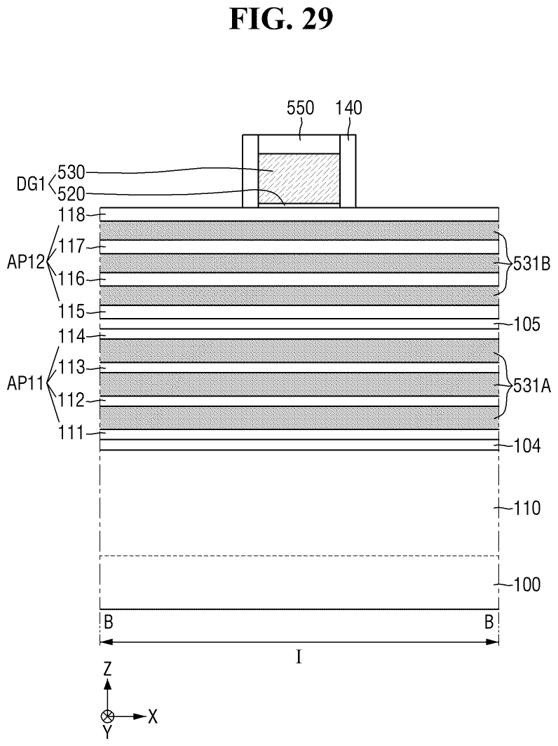

Referring to FIGS. 27 to 29, a dummy gate structure DG1 and the first gate spacer 140 are formed on the first area I of the substrate 100. For reference, FIG. 28 is a cross-sectional view taken along line A-A of FIG. 27, and FIG. 29 is a cross-sectional view taken along line B-B of FIG. 27.

The dummy gate structure DG1 may intersect with the first lower active pattern AP11, the first lower sacrificial pattern 531A, the first upper active pattern AP12, and the first upper sacrificial pattern 531B. For example, the dummy gate structure DG1 may extend in the second direction Y while being disposed on the first side surface 102a of the wall structure 102.

In some embodiments, the dummy gate structure DG1 may include a dummy gate dielectric film 520 and a dummy gate electrode 530. For example, a dielectric film and an electrode film that are sequentially stacked may be formed on the first area I of the substrate 100. Subsequently, a gate mask 550 extending in the second direction Y may be formed on the electrode film on the first area I. Subsequently, a patterning process may be performed to pattern the dielectric film and the electrode film using the gate mask 550 as an etch mask. The patterned dielectric film may form the dummy gate dielectric film 520. The patterned electrode film may form the dummy gate electrode 530.

The dummy gate structure DG1 may have etch selectivity relative to the first lower active pattern AP11, the first lower sacrificial pattern 531A, the first upper active pattern AP12, and the first upper sacrificial pattern 531B. In one example, the dummy gate electrode 530 may include a poly silicon (poly Si) film.

Subsequently, the first gate spacer 140 may be formed on a side surface of the dummy gate structure DG1. The first gate spacer 140 may extend along the side surface of the dummy gate structure DG1. The first gate spacer 140 may include, for example, at least one of silicon nitride, silicon oxynitride, silicon oxycarbide, silicon boron nitride, silicon boron carbonitride, silicon oxycarbonitride, and combinations thereof. However, embodiments of the present disclosure are not limited thereto.

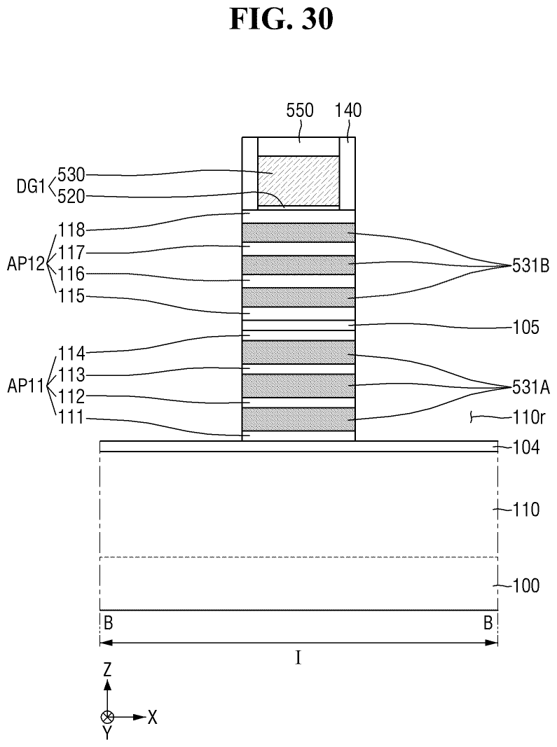

Referring to FIG. 30, an etching process is performed on the first lower active pattern AP11, the first lower sacrificial pattern 531A, the first upper active pattern AP12, and the first upper sacrificial pattern 531B.

For example, the etching process may use the dummy gate structure DG1 and the first gate spacer 140 as an etch mask. As the etching process is performed, a first recess 110r may be formed on an outer side surface of the dummy gate structure DG1. In some embodiments, the first recess 110r may be defined on an upper surface of the first base insulating film 104.

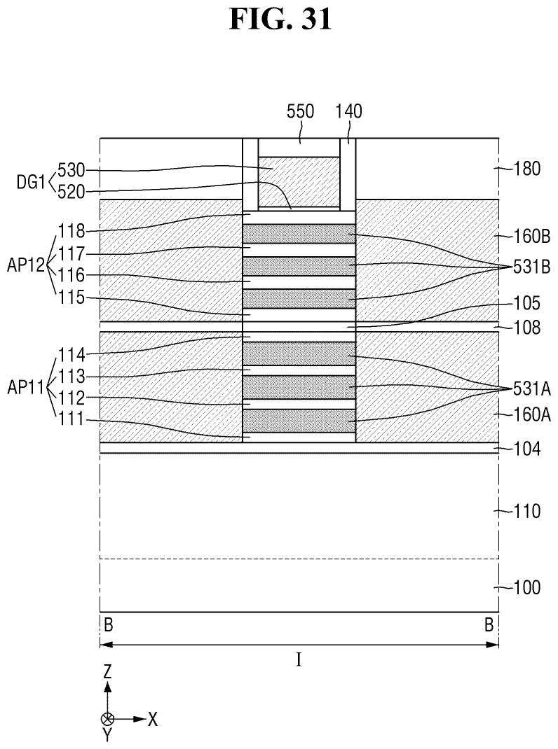

Referring to FIG. 31, the first lower source/drain pattern 160A, the first upper source/drain pattern 160B, and the interlayer insulating film 180 are formed.

The first lower source/drain pattern 160A may fill a lower portion of the first recess 110r. For example, an epitaxial growth process may be performed using the first lower active pattern AP11 as a seed layer. Thus, the first lower source/drain pattern 160A contacting the first lower active pattern AP11 may be formed.

The first upper source/drain pattern 160B may fill an upper portion of the first recess 110r. For example, the first isolation insulating film 108 may be formed to cover the first lower source/drain pattern 160A and not to cover the first upper active pattern AP12 so as to be exposed. Subsequently, an epitaxial growth process using the first upper active pattern AP12 as a seed layer may be performed. Thus, the first upper source/drain pattern 160B contacting the first upper active pattern AP12 may be formed.

Subsequently, the interlayer insulating film 180 may be formed to cover the first upper source/drain pattern 160B. The interlayer insulating film 180 may include at least one of, for example, silicon oxide, silicon nitride, silicon oxynitride, silicon oxycarbide, silicon boron nitride, silicon boron carbonitride, silicon oxycarbonitride, and low dielectric constant materials with a dielectric constant lower than that of silicon oxide. However, embodiments of the present disclosure are not limited thereto.

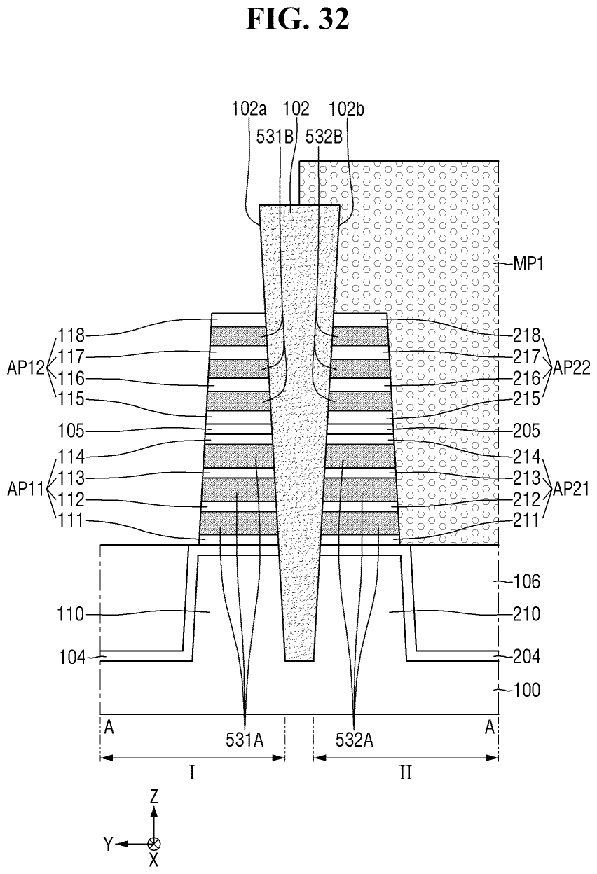

Referring to FIG. 32, the dummy gate structure DG1 is removed.

The dummy gate structure DG1 may have an etch selectivity relative to the first lower active pattern AP11, the first lower sacrificial pattern 531A, the first upper active pattern AP12, and the first upper sacrificial pattern 531B and thus may be selectively removed. As the dummy gate structure DG1 is removed, the first lower active pattern AP11, the first lower sacrificial pattern 531A, the first upper active pattern AP12 and The first upper sacrificial pattern 531B may be exposed.

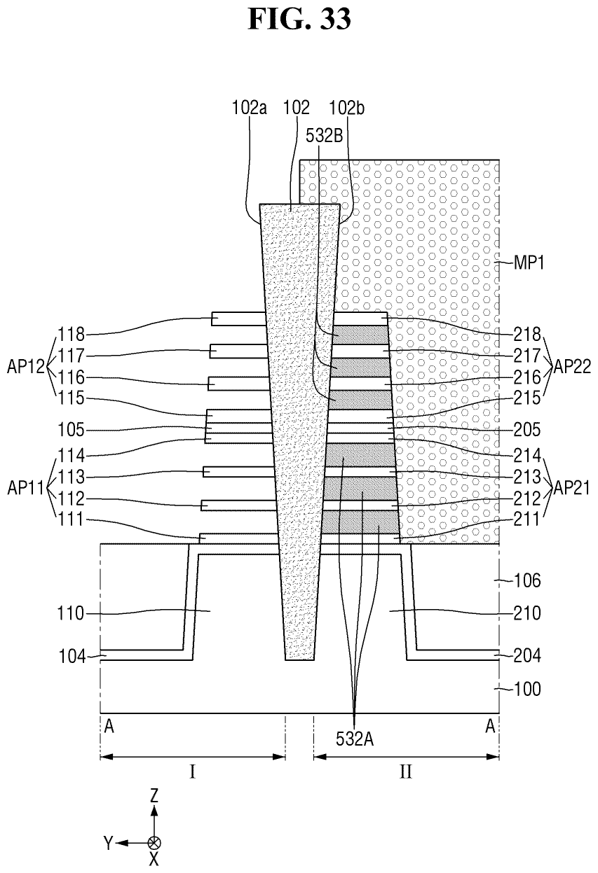

Referring to FIG. 33, the first lower sacrificial pattern 531A and the first upper sacrificial pattern 531B are removed.

Each of the first lower sacrificial pattern 531A and the first upper sacrificial pattern 531B may have an etch selectivity with respect to the first lower active pattern AP11 and the first upper active pattern AP12 and thus may be selectively removed.

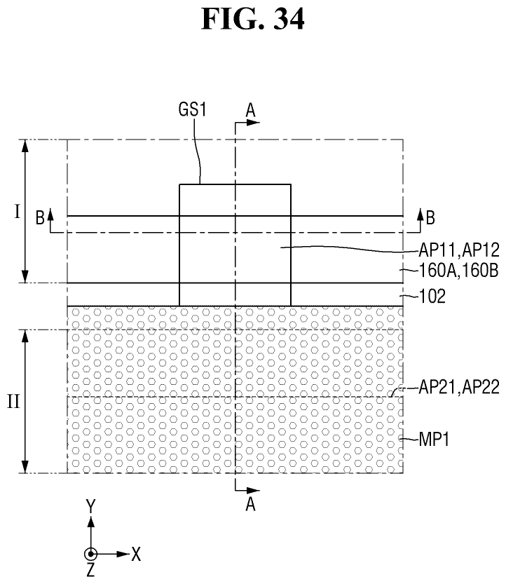

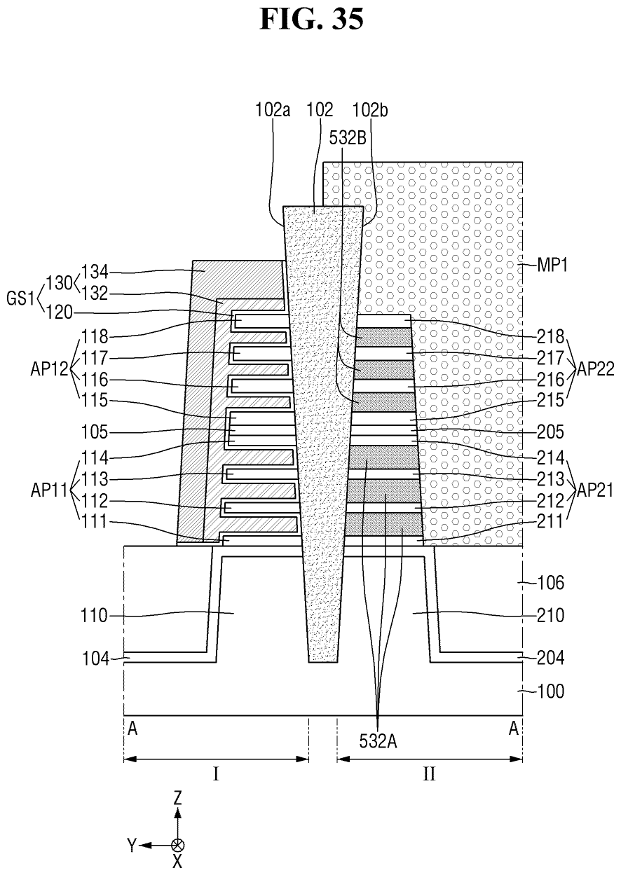

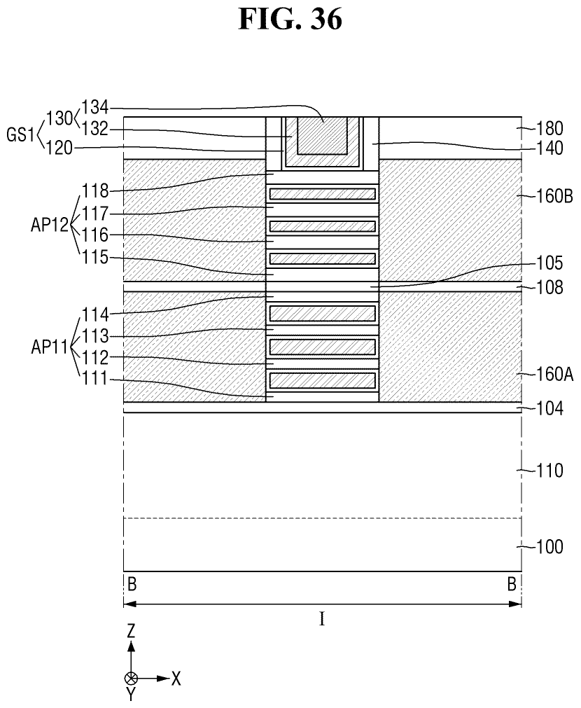

Referring to FIG. 34 to FIG. 36, the first gate structure GS1 is formed. For reference, FIG. 35 is a cross-sectional view taken along line A-A of FIG. 34, and FIG. 36 is a cross-sectional view taken along line B-B of FIG. 34.

For example, the first gate dielectric film 120 and the first gate electrode 130 may be sequentially stacked on the first lower active pattern AP11 and the first upper active pattern AP12. Subsequently, a patterning process may be performed on the first gate dielectric film 120 and the first gate electrode 130. Thus, the first gate structure GS1 may be formed to surround the perimeter of the at least one first lower bridge pattern 111 to 114 and the perimeter of the at least one first upper bridge pattern 115 to 118.

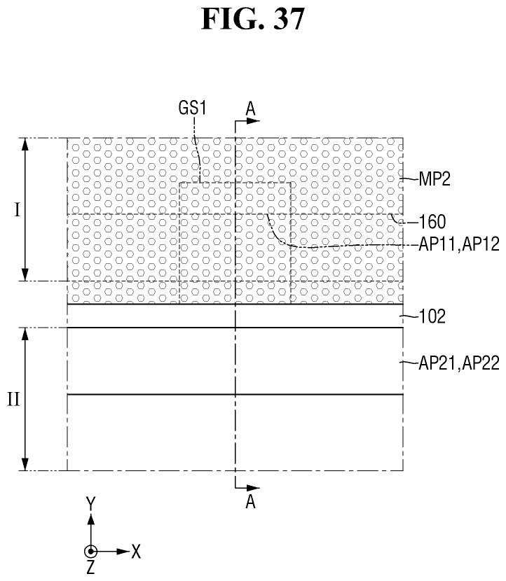

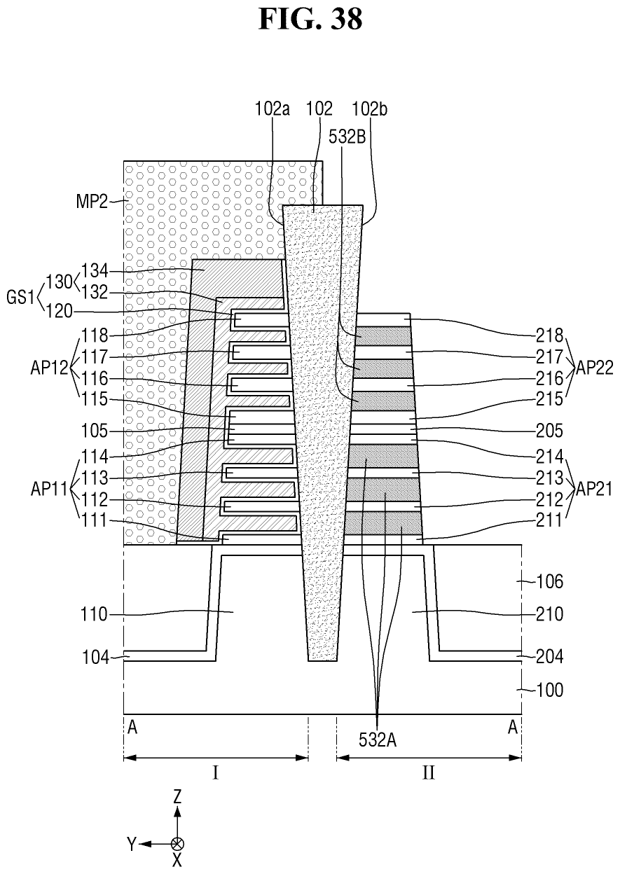

Referring to FIG. 37 and FIG. 38, a second mask pattern MP2 is formed on the first area I of the substrate 100. For reference, FIG. 38 is a cross-sectional view taken along line A-A of FIG. 37.

The second mask pattern MP2 may cover the first area I of the substrate 100. For example, the second mask pattern MP2 may cover the first lower active pattern AP11, the first upper active pattern AP12, the first lower source/drain pattern 160A, and the first upper source/drain pattern 160B, and the first gate structure GS1. The second mask pattern MP2 may cover at least a portion of the wall structure 102. However, embodiments of the present disclosure are not limited thereto.

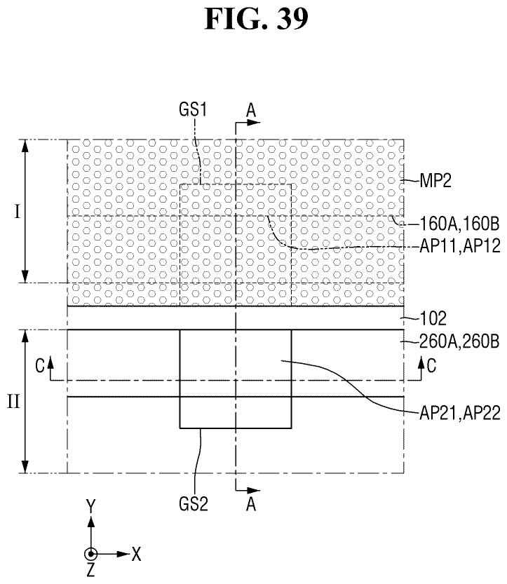

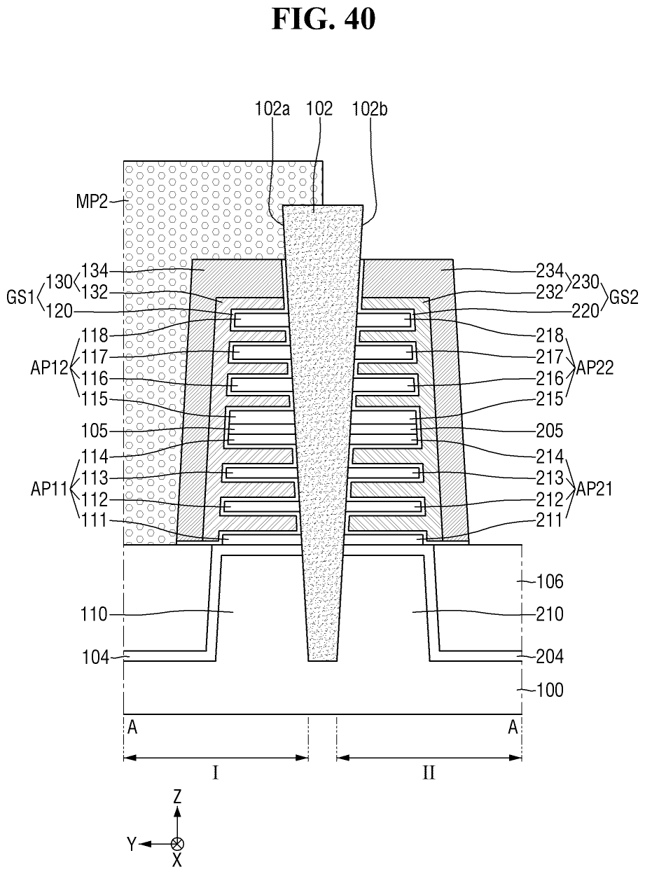

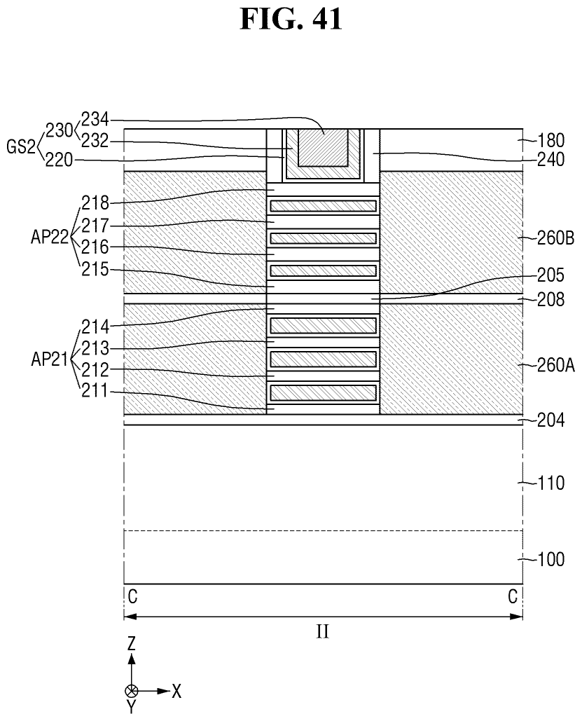

Referring to FIGS. 39 to 41, the second lower source/drain pattern 260A, the second upper source/drain pattern 260B, and the second gate structure GS2 are formed on the second area II of the substrate 100. For reference, FIG. 40 is a cross-sectional view taken along line A-A of FIG. 39, and FIG. 41 is a cross-sectional view taken along line B-B of FIG. 39. Except that the second lower source/drain pattern 260A, the second upper source/drain pattern 260B, and the second gate structure GS2 are formed on the second area II of the substrate 100, the second lower source/drain pattern 260A, the second upper source/drain pattern 260B, and the second gate structure GS2 may be formed in a similar manner to the above manner in which the first lower source/drain pattern 160A, the first upper source/drain pattern 160B, and the first gate structure GS1 are formed. Thus, detailed descriptions thereof are omitted below.

Next, referring to FIGS. 1 to 6, the first gate contact CB1 contacting the first gate structure GS1 and the second gate contact CB2 contacting the second gate structure GS2 are formed. Thus, the semiconductor device as described above with reference to FIGS. 1 to 6 may be manufactured.

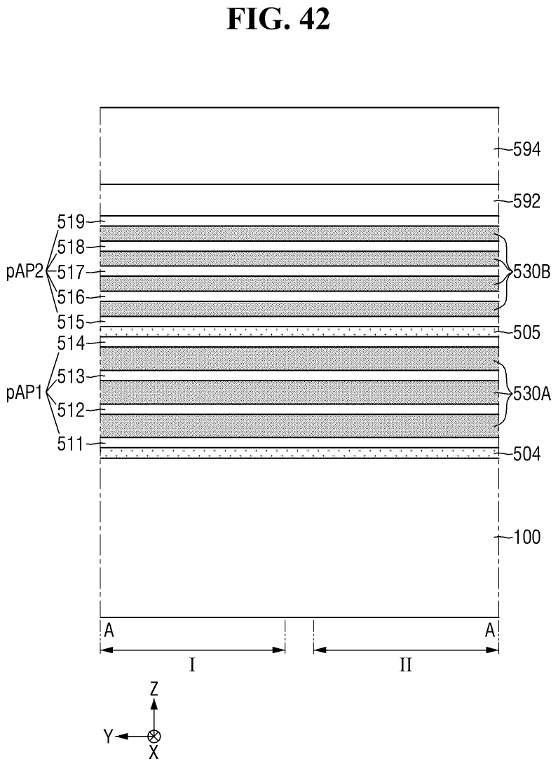

FIG. 42 is a diagram of an intermediate structure corresponding to an intermediate step of a method for manufacturing a semiconductor device according to some embodiments. For convenience of description, descriptions duplicate with those set forth above with reference to FIGS. 1 to 41 are briefly set forth or omitted.

Referring to FIG. 42, a second active film pAP2 may include at least one upper active film (e.g., upper active films 515 to 519) that are sequentially stacked on the middle sacrificial film 505. For reference, FIG. 42 is another cross-sectional view taken along line A-A of FIG. 16.

In some embodiments, the number of the upper active films 515 to 519 may be greater than the number of the lower active films 511 to 514.

Subsequently, the steps as described above with reference to FIGS. 18 to 41 may be performed. Thus, the semiconductor device as described above with reference to FIG. 8 and FIG. 9 may be manufactured.

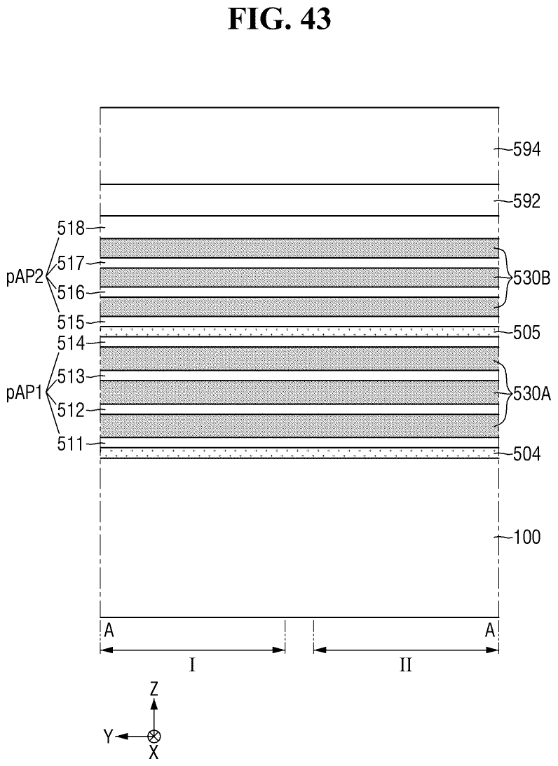

FIG. 43 is a diagram of an intermediate structure corresponding to an intermediate step of a method for manufacturing a semiconductor device according to some embodiments. For convenience of description, descriptions duplicate with those set forth above with reference to FIGS. 1 to 41 are briefly set forth or omitted.

Referring to FIG. 43, a second active film pAP2 may include at least one upper active film (e.g., upper active films 515 to 518) that are sequentially stacked on the middle sacrificial film 505. For reference, FIG. 43 is another cross-sectional view taken along line A-A of FIG. 16.

In some embodiments, each of some of the plurality of upper active films 515 to 519 may have a thickness different from a thickness of each of the others of the plurality of upper active films 515 to 519.

Subsequently, the steps as described above with reference to FIGS. 18 to 41 may be performed. Thus, the semiconductor device as described above with reference to FIG. 10 and FIG. 11 may be manufactured.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

1. A semiconductor device comprising:
a substrate;
a wall structure disposed on the substrate and extending in a first direction, wherein the wall structure includes a first side surface and a second side surface opposite to the first side surface in a second direction intersecting the first direction;
a first lower active pattern disposed on the first side surface and including at least one first lower bridge pattern spaced apart from the substrate;
a first upper active pattern disposed on the first side surface and including at least one first upper bridge pattern spaced further apart from the substrate than the first lower active pattern;
a first gate structure disposed on the first side surface and intersecting the first lower active pattern and the first upper active pattern;
a second lower active pattern disposed on the second side surface and including at least one second lower bridge pattern spaced apart from the substrate;
a second upper active pattern disposed on the second side surface and including at least one second upper bridge pattern spaced apart from the substrate than the second lower active pattern; and
a second gate structure disposed on the second side surface and intersecting the second lower active pattern and the second upper active pattern,
wherein a width in the second direction of the wall structure increases as the wall structure extends away from the substrate.

2. The semiconductor device of claim 1, wherein:
the at least one first lower bridge pattern is a plurality of lower sheet patterns and the at least one first upper bridge pattern is a plurality of upper sheet patterns, and
a width in the second direction of each sheet pattern of the plurality of upper sheet patterns is smaller than a width in the second direction of each sheet pattern of the plurality of lower sheet patterns.

3. The semiconductor device of claim 1, wherein a third direction intersects the first direction and the second direction, wherein a thickness in the third direction of each bridge pattern of the at least one first upper bridge pattern is greater than a thickness in the third direction of each bridge pattern of the at least one first lower bridge pattern.

4. The semiconductor device of claim 1, wherein a number of bridge patterns of the at least one first upper bridge pattern is greater than a number of bridge patterns of the at least one first lower bridge pattern.

5. The semiconductor device of claim 1, further comprising a base insulating film disposed between the substrate and the first lower active pattern so as to electrically insulate the substrate and the first lower active pattern from each other.

6. The semiconductor device of claim 1, further comprising a middle insulating film disposed between the first lower active pattern and the first upper active pattern so as to electrically insulate the first lower active pattern and the first upper active pattern from each other.

7. The semiconductor device of claim 1, wherein the first gate structure includes a gate dielectric film and a gate electrode sequentially stacked on the first lower active pattern and the first upper active pattern,
wherein a portion of the gate dielectric film is interposed between the wall structure and the gate electrode.

8. The semiconductor device of claim 1, further comprising:
a first lower source/drain pattern disposed on a side surface of the first gate structure and contacting the first lower active pattern in the first direction;
a first upper source/drain pattern disposed on the side surface of the first gate structure and contacting the first upper active pattern in the first direction;
a second lower source/drain pattern disposed on a side surface of the second gate structure and contacting the second lower active pattern in the first direction; and
a second upper source/drain pattern disposed on the side surface of the second gate structure and contacting the second upper active pattern in the first direction.

9. The semiconductor device of claim 8, wherein each of the first lower source/drain pattern and the first upper source/drain pattern includes impurities of a first conductivity type,
wherein each of the second lower source/drain pattern and the second upper source/drain pattern includes impurities of a second conductivity type different from the first conductivity type.

10. The semiconductor device of claim 8, wherein each of the first lower source/drain pattern and the second lower source/drain pattern includes impurities of a first conductivity type,
wherein each of the first upper source/drain pattern and the second upper source/drain pattern includes impurities of a second conductivity type different from the first conductivity type.

11. A semiconductor device comprising:
a substrate;
a wall structure disposed on the substrate and extending in a first direction, wherein the wall structure includes a first side surface and a second side surface opposite to the first side surface in a second direction intersecting the first direction;
a first lower active pattern disposed on the first side surface and including at least one first lower bridge pattern spaced apart from the substrate;
a first upper active pattern disposed on the first side surface and including at least one first upper bridge pattern spaced further apart from the substrate than the first lower active pattern;
a first gate structure disposed on the first side surface and intersecting the first lower active pattern and the first upper active pattern;
a second lower active pattern disposed on the second side surface, and including at least one second lower bridge pattern spaced apart from the substrate;
a second upper active pattern disposed on the second side surface and including at least one second upper bridge pattern spaced further apart from the substrate than the second lower active pattern; and
a second gate structure disposed on the second side surface and intersecting the second lower active pattern and the second upper active pattern,
wherein a width in the second direction of each bridge pattern of the at least one first upper bridge pattern is smaller than a width in the second direction of each bridge pattern of the at least one first lower bridge pattern,
wherein a third direction intersects the first direction and the second direction, wherein a thickness in the third direction of each bridge pattern of the at least one first upper bridge pattern is greater than a thickness in the third direction of each bridge pattern of the at least one first lower bridge pattern.

12. The semiconductor device of claim 11, wherein a width in the second direction of the wall structure increases as the wall structure extends away from the substrate.

13. The semiconductor device of claim 11, wherein a thickness in the third direction of each bridge pattern of the at least one second upper bridge pattern is greater than a thickness in the third direction of each bridge pattern of the at least one second lower bridge pattern.

14. The semiconductor device of claim 11, wherein the at least one first lower bridge pattern includes a first lower sheet pattern and an adjacent second lower sheet pattern sequentially stacked on the substrate and spaced apart from each other,
wherein the at least one first upper bridge pattern includes a first upper sheet pattern and an adjacent second upper sheet pattern sequentially stacked on the first lower active pattern and spaced apart from each other,
wherein a spacing in the third direction between the first upper sheet pattern and the second upper sheet pattern is smaller than a spacing in the third direction between the first lower sheet pattern and the second lower sheet pattern.

15. The semiconductor device of claim 11, wherein an area size of a cross section intersecting the first direction of the first upper active pattern is equal to an area size of a cross section intersecting the first direction of the first lower active pattern.

16. A semiconductor device comprising:
a substrate;
a wall structure disposed on the substrate and extending in a first direction, wherein the wall structure includes a first side surface and a second side surface opposite to the first side surface in a second direction intersecting the first direction;
a first lower active pattern disposed on the first side surface and including at least one first lower sheet pattern spaced apart from the substrate;
a first upper active pattern disposed on the first side surface and including at least one first upper sheet pattern spaced further apart from the substrate than the first lower active pattern;
a first gate structure disposed on the first side surface and intersecting the first lower active pattern and the first upper active pattern;
a second lower active pattern disposed on the second side surface and including at least one second lower sheet pattern spaced apart from the substrate;
a second upper active pattern disposed on the second side surface and including at least one second upper sheet pattern spaced further apart from the substrate than the second lower active pattern; and
a second gate structure disposed on the second side surface and intersecting the second lower active pattern and the second upper active pattern,
wherein a width in the second direction of each sheet pattern of the at least one first upper sheet pattern is smaller than a width in the second direction of each sheet pattern of the at least one first lower sheet pattern,
wherein a number of sheet patterns in the at least one first upper sheet pattern is greater than a number of sheet patterns in the at least one first lower sheet pattern.

17. The semiconductor device of claim 16, wherein a width in the second direction of the wall structure increases as the wall structure extends away from the substrate.

18. The semiconductor device of claim 16, wherein a number of sheet patterns in the at least one second upper sheet pattern is greater than a number of sheet patterns in the at least one second lower sheet pattern.

19. The semiconductor device of claim 16, wherein the at least one first lower sheet pattern includes a lower sheet pattern and an adjacent lower sheet pattern sequentially stacked on the substrate and spaced apart from each other,
wherein the at least one first upper sheet pattern includes an upper sheet pattern and an adjacent upper sheet pattern sequentially stacked on the first lower active pattern and spaced apart from each other,
wherein a spacing between the upper sheet pattern and the adjacent upper sheet pattern in a third direction perpendicular to the first direction and the second direction is smaller than a spacing between the lower sheet pattern and the adjacent lower sheet pattern in the third direction.

20. The semiconductor device of claim 16, wherein an area size of a cross section intersecting the first direction of the first upper active pattern is equal to an area size of a cross section intersecting the first direction of the first lower active pattern.

21-27. (canceled)
